(19) United States
(12) Patent Application Publication
(10) Pub. No.: US 2025/0255100 A1
(43) Pub. Date: Aug. 7, 2025

(54) DISPLAY INCLUDING STRUCTURE FOR REDUCING DAMAGE AND ELECTRONIC DEVICE COMPRISING SAME

(71) Applicant: Samsung Electronics Co., Ltd., Suwon-si (KR)

(72) Inventors: Sungyoung SHIN, Suwon-si (KR); Minsuk UHM, Suwon-si (KR); Dongseop LEE, Suwon-si (KR); Haechang LEE, Suwon-si (KR); Seongdae CHOI, Suwon-si (KR); Kwangtai KIM, Suwon-si (KR); Donghyun YEOM, Suwon-si (KR)

(21) Appl. No.: 19/186,218

(22) Filed: Apr. 22, 2025

Related U.S. Application Data
(63) Continuation of application No. PCT/KR2023/015659, filed on Oct. 12, 2023.

(30) Foreign Application Priority Data
Oct. 31, 2022 (KR) 10-2022-0142531
Nov. 16, 2022 (KR) 10-2022-0153793

(51) Int. Cl. H10K 59/121; H04M 1/02; H10D 86/40; H10D 86/60; H10K 59/124; H10K 59/131; H10K 59/80; H10K 59/88; H10K 102/00

(52) U.S. Cl. CPC H10K 59/1213; H04M 1/0216; H10D 86/443; H10D 86/60; H10K 59/124; H10K 59/131; H10K 59/873; H10K 59/88; H10K 2102/311

(57) ABSTRACT

A display comprises: a pixel layer including a first region, a second region, a deformation region, a plurality of first subpixels disposed in the first region, a plurality of second subpixels disposed in the second region, and a plurality of third subpixels disposed in the deformation region; and a plurality of TFTs disposed under the pixel layer, wherein the plurality of TFTs comprise: a plurality of first TFTs configured to drive the plurality of first subpixels, the plurality of first TFTs being disposed in the first region; a plurality of second TFTs configured to drive the plurality of second subpixels, the plurality of second TFTs being disposed in the second region; and a plurality of third TFTs configured to drive at least some of the plurality of third subpixels, the plurality of third TFTs being disposed outside the deformation region.

### CROSS-REFERENCE TO RELATED APPLICATIONS

This application is a continuation of International Application No. PCT/KR2023/015659, designating the United States, filed on Oct. 12, 2023, in the Korean Intellectual Property Receiving Office and claiming priority to Korean Patent Application Nos. 10-2022-0142531, filed on Oct. 31, 2022, and 10-2022-0153793, filed on Nov. 16, 2022, in the Korean Intellectual Property Office, the disclosures of each of which are incorporated by reference herein in their entireties.

### BACKGROUND

### Field

The present disclosure relates to a display including a structure for reducing damage and an electronic device including the same.

### Description of Related Art

There is an increasing need for an electronic device that may change a size of a display for displaying contents, so that a user may receive various contents through the electronic device. For example, the electronic device may provide a structure in which the size of the display for displaying contents may be changed by including a foldable flexible display.

The above-described information may be provided as a related art for the purpose of helping understanding of the present disclosure. No assertion or decision is made as to whether any of the above description may be applied as a prior art related to the present disclosure.

### SUMMARY

According to an example embodiment, a display may comprise: a first region; a second region movable with respect to the first region; a deformation region, disposed between the first region and the second region, deformable by movement of the second region with respect to the first region; a pixel layer including a plurality of first sub-pixels disposed within the first region, a plurality of second sub-pixels disposed within the second region, and a plurality of third sub-pixels disposed within the deformation region; and a plurality of thin film transistors (TFTs) disposed below the pixel layer, wherein the plurality of TFTs may include a plurality of first TFTs configured to drive the plurality of first sub-pixels, disposed in the first region, the plurality of TFTs may include a plurality of second TFTs configured to drive the plurality of second sub-pixels, disposed in the second region, the plurality of TFTs may include a plurality of third TFTs configured to drive at least a portion of the plurality of third sub-pixels, and disposed outside the deformation region.

According to an example embodiment, an electronic device may comprise: a first housing; a second housing coupled to the first housing to be rotatable with respect to the first housing; a display including a first region, a second region spaced apart from the first region, and a deformation region connecting the first region and the second region and being deformable by movement of the second housing with respect to the first housing, wherein the display may comprise a pixel layer including a plurality of first sub-pixels disposed within the first region, a plurality of second sub-pixels disposed within the second region, and a plurality of third sub-pixels disposed within the deformation region; and a plurality of thin film transistors (TFTs) disposed below the pixel layer, wherein the plurality of TFTs may include a plurality of first TFTs configured to drive the plurality of first sub-pixels, disposed in the first region, a plurality of second TFTs configured to drive the plurality of second sub-pixels, disposed in the second region, and a plurality of third TFTs configured to drive at least a portion of the plurality of third sub-pixels, and disposed outside the deformation region.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a block diagram illustrating an example configuration of a display module according to various embodiments;

FIG. 3A is a diagram illustrating an example of an unfolding state of an example electronic device according to various embodiments;

FIG. 3B is a diagram illustrating an example of a folding state of an example electronic device according to various embodiments

FIG. 3C is an exploded perspective view of an example electronic device according to various embodiments;

FIG. 4A is a diagram illustrating a top plan view of an unfolding state of an electronic device according to various embodiments;

FIG. 4B is a graph illustrating a relationship between stress and a distance from a folding axis within an example display according to various embodiments;

FIG. 5A is a cross-sectional view illustrating an example of a display of an example electronic device taken along line A-A′ of FIG. 4A according to various embodiments;

FIG. 5B is a cross-sectional view illustrating an example of a display of an example electronic device taken along line B-B′ of FIG. 4A according to various embodiments;

FIG. 6 is a cross-sectional view illustrating an example of a display of an example electronic device taken along line C-C′ of FIG. 4A according to various embodiments;

FIG. 7 is a cross-sectional view illustrating an example of cutting a display of an example electronic device according to various embodiments;

FIG. 8 is a cross-sectional view illustrating an example of cutting a display of an example electronic device according to various embodiments;

FIG. 9 is a diagram illustrating a top plan view in an unfolding state of an example electronic device according to various embodiments; and

FIG. 10 is a diagram illustrating a top plan view in an unfolding state of an example electronic device according to various embodiments.

### DETAILED DESCRIPTION

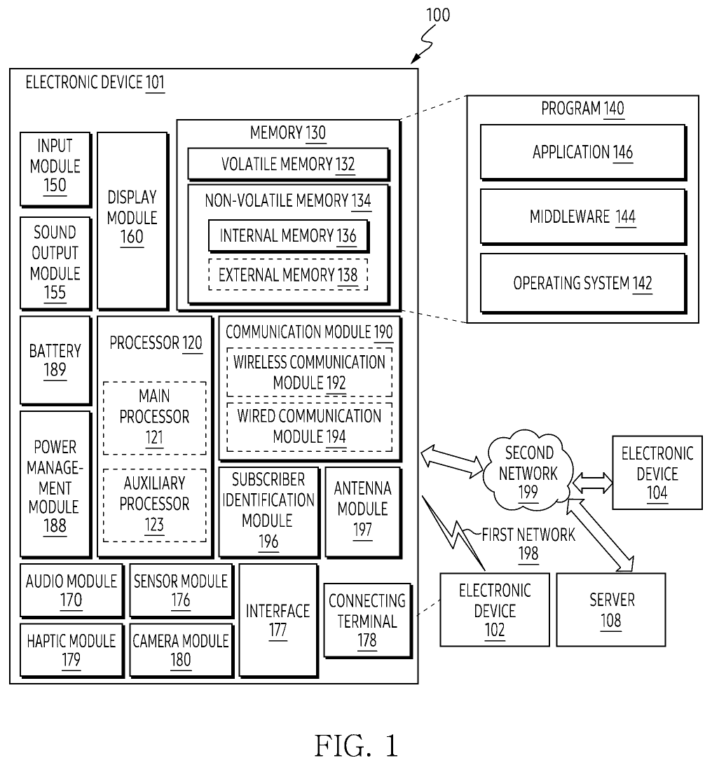

FIG. 1 is a block diagram illustrating an example electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional M IMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

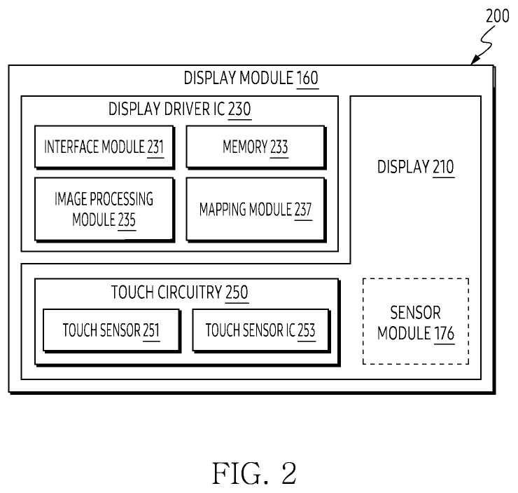

FIG. 2 is a block diagram 200 illustrating an example configuration of the display module 160 according to various embodiments.

Referring to FIG. 2, the display module 160 may include a display 210 and a display driver integrated circuit (DDI) 230 to control the display 210. The DDI 230 may include an interface module (e.g., including interface circuitry) 231, memory 233 (e.g., buffer memory), an image processing module (e.g., including image processing circuitry) 235, and/or a mapping module (e.g., including various circuitry and/or executable program instructions) 237.

The DDI 230 may receive image information that contains image data or an image control signal corresponding to a command to control the image data from another component of the electronic device 101 via the interface module 231. For example, according to an embodiment, the image information may be received from the processor 120 (e.g., the main processor 121 (e.g., an application processor)) or the auxiliary processor 123 (e.g., a graphics processing unit) operated independently from the function of the main processor 121. The DDI 230 may communicate, for example, with touch circuitry 250 or the sensor module 176 via the interface module 231. The DDI 230 may also store at least part of the received image information in the memory 233, for example, on a frame by frame basis. The image processing module 235 may perform pre-processing or post-processing (e.g., adjustment of resolution, brightness, or size) with respect to at least part of the image data. According to an embodiment, the pre-processing or post-processing may be performed, for example, based at least in part on one or more characteristics of the image data or one or more characteristics of the display 210. The mapping module 237 may generate a voltage value or a current value corresponding to the image data pre-processed or post-processed by the image processing module 235. According to an embodiment, the generating of the voltage value or current value may be performed, for example, based at least in part on one or more attributes of the pixels (e.g., an array, such as an RGB stripe or a pentile structure, of the pixels, or the size of each subpixel). At least some pixels of the display 210 may be driven, for example, based at least in part on the voltage value or the current value such that visual information (e.g., a text, an image, or an icon) corresponding to the image data may be displayed via the display 210.

According to an embodiment, the display module 160 may further include the touch circuitry 250. The touch circuitry 250 may include a touch sensor 251 and a touch sensor IC 253 to control the touch sensor 251. The touch sensor IC 253 may control the touch sensor 251 to sense a touch input or a hovering input with respect to a certain position on the display 210. To achieve this, for example, the touch sensor 251 may detect (e.g., measure) a change in a signal (e.g., a voltage, a quantity of light, a resistance, or a quantity of one or more electric charges) corresponding to the certain position on the display 210. The touch circuitry 250 may provide input information (e.g., a position, an area, a pressure, or a time) indicative of the touch input or the hovering input detected via the touch sensor 251 to the processor 120. According to an embodiment, at least part (e.g., the touch sensor IC 253) of the touch circuitry 250 may be formed as part of the display 210 or the DDI 230, or as part of another component (e.g., the auxiliary processor 123) disposed outside the display module 160.

According to an embodiment, the display module 160 may further include at least one sensor (e.g., a fingerprint sensor, an iris sensor, a pressure sensor, or an illuminance sensor) of the sensor module 176 or a control circuit for the at least one sensor. In such a case, the at least one sensor or the control circuit for the at least one sensor may be embedded in one portion of a component (e.g., the display 210, the DDI 230, or the touch circuitry 250)) of the display module 160. For example, when the sensor module 176 embedded in the display module 160 includes a biometric sensor (e.g., a fingerprint sensor), the biometric sensor may obtain biometric information (e.g., a fingerprint image) corresponding to a touch input received via a portion of the display 210. A s another example, when the sensor module 176 embedded in the display module 160 includes a pressure sensor, the pressure sensor may obtain pressure information corresponding to a touch input received via a partial or whole area of the display 210. According to an embodiment, the touch sensor 251 or the sensor module 176 may be disposed between pixels in a pixel layer of the display 210, or over or under the pixel layer.

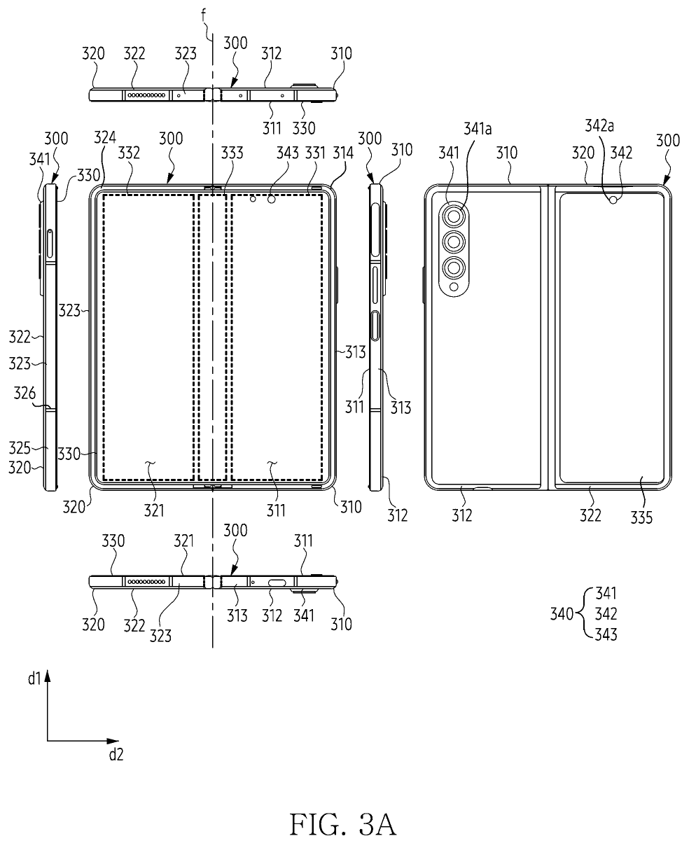

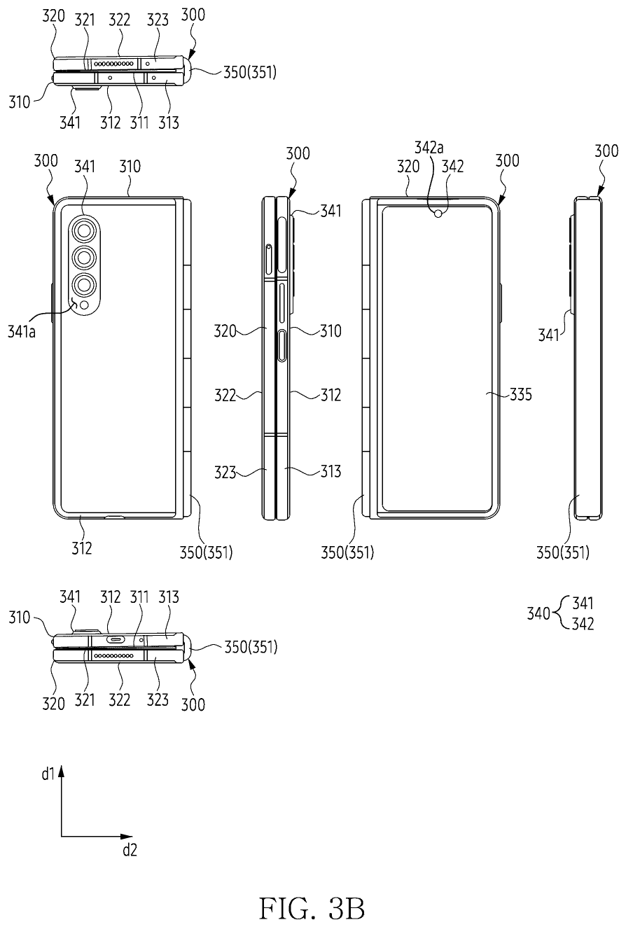

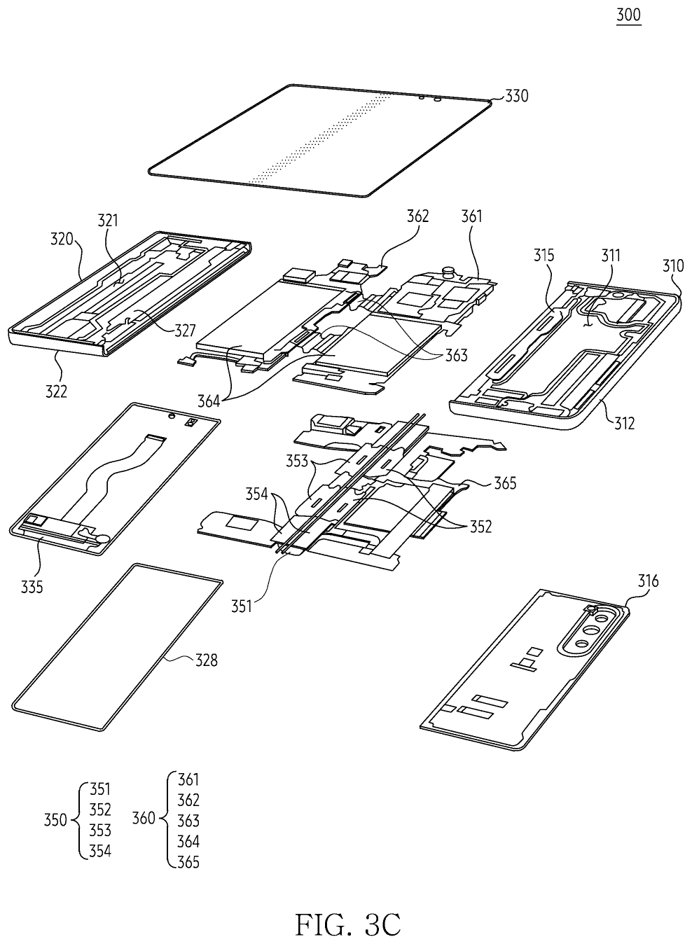

FIG. 3A is a diagram illustrating an example of an unfolding state of an example electronic device according to various embodiments, FIG. 3B is a diagram illustrating an example of a folding state of an example electronic device according to various embodiments, and FIG. 3C is an exploded perspective view of an example electronic device according to various embodiments.

Referring to FIGS. 3A, 3B, and 3C, an electronic device 300 (e.g., the electronic device 101 of FIG. 1) may include a first housing 310, a second housing 320, and a display 330 (e.g., the display 210 of FIG. 2), at least one camera 340 (e.g., the camera module 180 of FIG. 1), a hinge structure 350, and/or at least one electronic component 360.

The first housing 310 and the second housing 320 may form at least a portion of an outer surface of the electronic device 300 that may be gripped by a user. The at least a portion of the outer surface of the electronic device 300 defined by the first housing 310 and the second housing 320 may contact a part of a body of the user when the electronic device 300 is used by the user. According to an embodiment, the first housing 310 may include a first surface 311, a second surface 312 facing the first surface 311 and spaced apart from the first surface 311, and a first side surface 313 surrounding at least a portion of the first surface 311 and the second surface 312. The first side surface 313 may connect a periphery of the first surface 311 to a periphery of the second surface 312. The first surface 311, the second surface 312, and the first side surface 313 may define an inner space of the first housing 310. According to an embodiment, the first housing 310 may provide the space formed by the first surface 311, the second surface 312, and the first side surface 313 as a space for disposing components of the electronic device 300.

According to an embodiment, the second housing 320 may include a third surface 321, a fourth surface 322 facing the third surface 321 and spaced apart from the third surface 321, and a second side surface 323 surrounding at least a portion of the third surface 321 and the fourth surface 322. The second side surface 323 may connect a periphery of the third surface 321 to a periphery of the fourth surface 322. The third surface 321, the fourth surface 322, and the second side surface 323 may define an inner space of the second housing 320. According to an embodiment, the second housing 320 may provide the space formed by the third surface 321, the fourth surface 322, and the second side surface 323 surrounding at least a portion of the third surface 321 and the fourth surface 322, as a space for mounting components of the electronic device 101. According to an embodiment, the second housing 320 may be coupled to the first housing 310 to be rotatable with respect to the first housing 310.

According to an embodiment, each of the first housing 310 and the second housing 320 may include a first protective member 314 and a second protective member 324, respectively. The first protective member 314 and the second protective member 324 may be disposed on the first surface 311 and the third surface 321 along a periphery of the display 330. According to an embodiment, the first protective member 314 and the second protective member 324 may prevent and/or reduce an inflow of a foreign matter (e.g., dust or moisture) through a gap between the display 330, and the first housing 310 and the second housing 320. For example, the first protective member 314 may surround a periphery of a first display region 331 of the display 330, and the second protective member 324 may surround a periphery of a second display region 332 of the display 330. The first protective member 314 may be formed by being attached to the first side surface 313 of the first housing 310 or may be formed integrally with the first side surface 313. The second protective member 324 may be formed by being attached to the second side surface 323 of the second housing 320 or may be integrally formed with the second side surface 323.

According to an embodiment, the first side surface 313 and the second side surface 323 may include a conductive material, a non-conductive material, or a combination thereof. For example, the second side surface 323 may include at least one conductive member 325 and at least one non-conductive member 326. The at least one conductive member 325 may include a plurality of conductive members spaced apart from each other. The at least one non-conductive member 326 may be disposed between the plurality of conductive members. The plurality of conductive members may be disconnected from each other by the at least one non-conductive member 326 disposed between the plurality of conductive members. According to an embodiment, the plurality of conductive members and a plurality of non-conductive members may form an antenna radiator together. The electronic device 300 may communicate with an external electronic device through the antenna radiator formed by the plurality of conductive members and the plurality of non-conductive members.

The display 330 may be configured to display visual information. According to an embodiment, the display 330 may be disposed on the first surface 311 of the first housing 310 and the third surface 321 of the second housing 320 across the hinge structure 350. For example, the display 330 may include the first display region 331 disposed on the first surface 311 of the first housing, the second display region 332 disposed on the third surface 321 of the second housing, and a third display region 333 disposed between the first display region 331 and the second display region 332. The first display region 331, the second display region 332, and the third display region 333 may form a front surface of the display 330. According to an embodiment, the display 330 may further include a sub-display panel 335 disposed on the fourth surface 322 of the second housing 320. For example, the display 330 may be referred to as a flexible display. According to an embodiment, the display 330 may include a window exposed toward the outside of the electronic device 300. The window may protect a surface of the display 330 and transmit visual information provided by the display 330 to the outside of the electronic device 300 by including a substantially transparent material. For example, the window may include glass (e.g., ultra-thin glass (UTG)) and/or polymer (e.g., polyimide (PI)), but is not limited thereto.

At least one camera 340 may be configured to obtain an image based on receiving light from an external subject of the electronic device 300. According to an embodiment, the at least one camera 340 may include first cameras 341, a second camera 342, and a third camera 343. The first cameras 341 may be disposed in the first housing 310. For example, the first cameras 341 may be disposed inside the first housing 310, and at least a portion may be visible through the second surface 312 of the first housing 310. The first cameras 341 may be supported by a bracket (not illustrated) in the first housing 310. The first housing 310 may include at least one opening 341a overlapping the first cameras 341 when the second surface 312 is viewed from above. The first cameras 341 may obtain an image based on receiving light from the outside of the electronic device 300 through the at least one opening 341a.

According to an embodiment, the second camera 342 may be disposed in the second housing 320. For example, the second camera 342 may be disposed inside the second housing 320 and may be visible through the sub-display panel 335. The second housing 320 may include at least one opening 342a overlapping the second camera 342 when the fourth surface 322 is viewed from above. The second camera 342 may obtain an image based on receiving light from the outside of the electronic device 300 through the at least one opening 342a.

According to an embodiment, the third camera 343 may be disposed in the first housing 310. For example, the third camera 343 may be disposed inside the first housing 310, and at least a portion may be visible through the first surface 311 of the first housing 310. For another example, the third camera 343 may be disposed inside the first housing 310, and at least a portion may be visible through the first display region 331 of the display 330. The first display region 331 of the display 330 may include at least one opening (not illustrated) overlapping the third camera 343 when the display 330 is viewed from above. The third camera 343 may obtain an image based on receiving light from the outside of the display 330 through the at least one opening.

According to an embodiment, the second camera 342 and the third camera 343 may be disposed below (e.g., a direction toward the inside of the first housing 310 or the inside of the second housing 320) the display 330. For example, the second camera 342 and the third camera 343 may be an under display camera (UDC). In case that the second camera 342 and the third camera 343 are the under-display cameras, a region of the display 330 corresponding to each position of the second camera 342 and the third camera 343 may not be an inactive region. For example, in case that the second camera 342 and the third camera 343 are the under-display cameras, the region of the display 330 corresponding to each position of the second camera 342 and the third camera 343 may have pixel density lower than pixel density of another region of the display 330. The inactive region of the display 330 may refer, for example, to a region of the display 330 that does not include pixels or does not emit light to the outside of the electronic device 300. For another example, the second camera 342 and the third camera 343 may be a punch hole camera. In case that the second camera 342 and the third camera 343 are the punch hole cameras, the region of the display 330 corresponding to each position of the second camera 342 and the third camera 343 may be the inactive region. For example, in case that the second camera 342 and the third camera 343 are the punch-hole cameras, the region of the display 330 corresponding to each position of the second camera 342 and the third camera 343 may include an opening that does not include a pixel.

According to an embodiment, the hinge structure 350 may rotatably connect the first housing 310 and the second housing 320. The hinge structure 350 may be disposed between the first housing 310 and the second housing 320 of the electronic device 101 so that the electronic device 300 may be bent, curved, or folded. For example, the hinge structure 350 may be disposed between a portion of the first side surface 313 and a portion of the second side surface 323 facing each other. The hinge structure 350 may change the electronic device 300 into an unfolding state in which the first surface 311 of the first housing 310 and the third surface 321 of the second housing 320 face substantially the same direction as each other, or a folding state in which the first surface 311 and the third surface 321 face each other. When the electronic device 300 is in the folding state, the first housing 310 and the second housing 320 may be stacked or overlapped by facing each other.

According to an embodiment, when the electronic device 300 is in the folding state, a direction in which the first surface 311 faces and a direction in which the third surface 321 faces may be different from each other. For example, when the electronic device 300 is in the folding state, the direction in which the first surface 311 faces and the direction in which the third surface 321 faces may be opposite to each other. For another example, when the electronic device 300 is in the folding state, the direction in which the first surface 311 faces and the direction in which the third surface 321 faces may be inclined with respect to each other. In case that the direction in which the first surface 311 faces is inclined with respect to the direction in which the third surface 321 faces, the first housing 310 may be inclined with respect to the second housing 320.

According to an embodiment, the electronic device 300 may be foldable with respect to a folding axis f. The folding axis f may refer, for example, to an imaginary line extending through a hinge cover 351 in a direction (e.g., d1 of FIGS. 3A and 3B) substantially parallel to a longitudinal direction of the electronic device 300, but is not limited thereto. For example, the folding axis f may be an imaginary line extending in a direction (e.g., d2 of FIGS. 3A and 3B) substantially perpendicular to the longitudinal direction of the electronic device 300. In case that the folding axis f extends in the direction substantially perpendicular to the longitudinal direction of the electronic device 300, the hinge structure 350 may connect the first housing 310 and the second housing 320 by extending in a direction parallel to the folding axis f. The first housing 310 and the second housing 320 may be rotatable by the hinge structure 350 extending in the direction substantially perpendicular to the longitudinal direction of the electronic device 300.

According to an embodiment, the hinge structure 350 may include the hinge cover 351, a first hinge plate 352, a second hinge plate 353, and a hinge module 354. The hinge cover 351 may surround internal components of the hinge structure 350 and form an outer surface of the hinge structure 350. According to an embodiment, when the electronic device 300 is in the folding state, at least a portion of the hinge cover 351 surrounding the hinge structure 350 may be exposed to the outside of the electronic device 300 through a space between the first housing 310 and the second housing 320. According to an embodiment, when the electronic device 300 is in the unfolding state, the hinge cover 351 may not be exposed to the outside of the electronic device 300 by being covered by the first housing 310 and the second housing 320.

According to an embodiment, the first hinge plate 352 and the second hinge plate 353 may rotatably connect the first housing 310 and the second housing 320, by being coupled to the first housing 310 and the second housing 320, respectively. For example, the first hinge plate 352 may be coupled with a first front bracket 315 of the first housing 310, and the second hinge plate 353 may be coupled with a second front bracket 327 of the second housing 320. As the first hinge plate 352 and the second hinge plate 353 are coupled to the first front bracket 315 and the second front bracket 327, respectively, the first housing 310 and the second housing 320 may be rotatable according to rotation of the first hinge plate 352 and the second hinge plate 353.

The hinge module 354 may rotate the first hinge plate 352 and the second hinge plate 353. For example, the hinge module 354 may rotate the first hinge plate 352 and the second hinge plate 353 based on the folding axis f, by including gears that are rotatable by being engaged with each other. According to an embodiment, the hinge module 354 may be plural. For example, the plurality of hinge modules 354 may be disposed to be spaced apart from each other at both ends of the first hinge plate 352 and the second hinge plate 353, respectively.

According to an embodiment, the first housing 310 may include the first front bracket 315 and a first rear bracket 316, and the second housing 320 may include the second front bracket 327 and a second rear bracket 328. The first front bracket 315 and the first rear bracket 316 may support components of the electronic device 300. The first front bracket 315 may define the first housing 310 by being coupled to the first rear bracket 316. The first rear bracket 316 may define a portion of an outer surface of the first housing 310. The second front bracket 327 and the second rear bracket 328 may support components of the electronic device 300. The second front bracket 327 may define the second housing 320 by being coupled to the second rear bracket 328. The second rear bracket 328 may define a portion of an outer surface of the second housing 320. For example, the display 330 may be disposed on a surface of the first front bracket 315 and a surface of the second front bracket 327. The first rear bracket 316 may be disposed on another surface of the first front bracket 315 opposite to the surface of the first front bracket 315. The second rear bracket 328 may be disposed on another surface of the second front bracket 327 opposite to the surface of the second front bracket 327. The sub-display panel 335 may be disposed between the second front bracket 327 and the second rear bracket 328.

According to an embodiment, a portion of the first front bracket 315 may be surrounded by the first side surface 313, and a portion of the second front bracket 327 may be surrounded by the second side surface 323. For example, the first front bracket 315 may be integrally formed with the first side surface 313, and the second front bracket 327 may be integrally formed with the second side surface 323. For another example, the first front bracket 315 may be formed separately from the first side surface 313, and the second front bracket 327 may be formed separately from the second side surface 323.

The at least one electronic component 360 may implement various functions to be provided to the user. According to an embodiment, the at least one electronic component 360 may include a first printed circuit board 361, a second printed circuit board 362, a flexible printed circuit board 363, a battery 364 (e.g., the battery 189 of FIG. 1), and/or an antenna 365 (e.g., the antenna module 197 of FIG. 1). The first printed circuit board 361 and the second printed circuit board 362 may respectively form an electrical connection between components in the electronic device 300. For example, components (e.g., the processor 120 of FIG. 1) for implementing an overall function of the electronic device 300 may be disposed in the first printed circuit board 361, and electronic components for implementing some functions of the first printed circuit board 361 may be disposed in the second printed circuit board 362. For another example, components for an operation of the sub-display panel 335 disposed on the fourth surface 322 may be disposed on the second printed circuit board 362.

According to an embodiment, the first printed circuit board 361 may be disposed in the first housing 310. For example, the first printed circuit board 361 may be disposed on a surface of the first front bracket 315. According to an embodiment, the second printed circuit board 362 may be disposed in the second housing 320. For example, the second printed circuit board 362 may be spaced apart from the first printed circuit board 361 and disposed on a surface of the second front bracket 327. The flexible printed circuit board 363 may connect the first printed circuit board 361 and the second printed circuit board 362. For example, the flexible printed circuit board 363 may extend from the first printed circuit board 361 to the second printed circuit board 362.

The battery 364 is a device for supplying power to at least one component of the electronic device 300, and may include, for example, a non-rechargeable primary battery, a rechargeable secondary battery, or a fuel cell. At least a portion of the battery 364 may be disposed on substantially the same plane as the first printed circuit board 361 or the second printed circuit board 362.

The antenna 365 may be configured to receive power or a signal from the outside of the electronic device 300. According to an embodiment, the antenna 365 may be disposed between the first rear bracket 316 and the battery 364. The antenna 365 may include, for example, a near field communication (NFC) antenna, an antenna module, and/or a magnetic secure transmission (MST) antenna. The antenna 365 may, for example, perform short-range communication with an external device or wirelessly transmit and receive power required for charging.

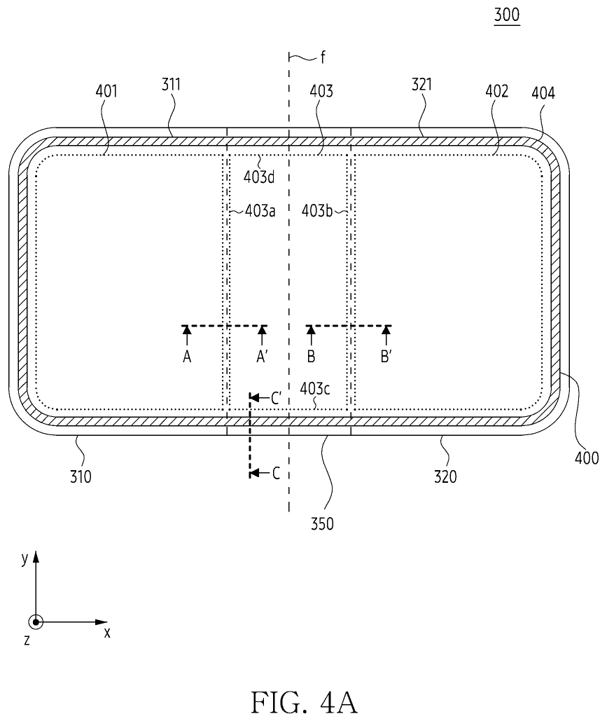

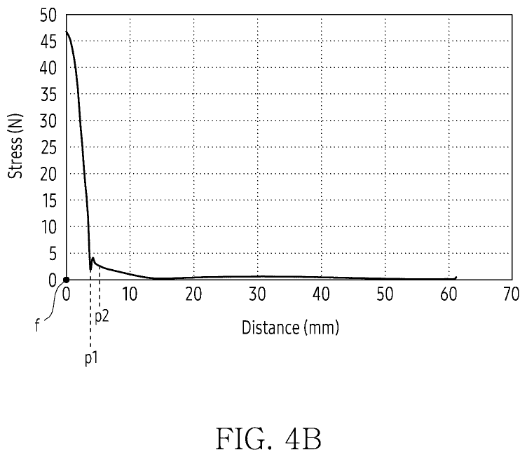

FIG. 4A is a diagram illustrating a top plan view of an unfolding state of an electronic device according to various embodiments, and FIG. 4B is a graph illustrating a relationship between stress and a distance from a folding axis within an example display according to various embodiments.

Referring to FIGS. 4A and 4B, an electronic device 300 according to an embodiment may include a first housing 310, a second housing 320, a hinge structure 350, and/or a display 400 (e.g., the display 210 of FIG. 2, the display 330 of FIGS. 3A, 3B, and 3C).

According to an embodiment, the first housing 310 and the second housing 320 may be coupled to be rotatable with respect to each other through the hinge structure 350. For example, in a folding state of the electronic device 300, a first surface 311 and a third surface 321 of the first housing 310 may face each other. For example, in an unfolding state of the electronic device 300, a direction (e.g., a +z direction) in which the first surface 311 of the first housing 310 faces may be substantially the same as a direction (e.g., the +z direction) in which the third surface 321 of the second housing 320 faces. As the first housing 310 and the second housing 320 move with respect to each other, the display 400 may be folded or unfolded. For example, in the unfolding state of the electronic device 300, the display 400 may be unfolded. For example, in the folding state of the electronic device 300, the display 400 may be folded. According to an embodiment, the display 400 may be folded or unfolded based on a folding axis f by movement of the second housing 320 with respect to the first housing 310.

According to an embodiment, the display 400 may be configured to provide visual information. The display 400 may include a first region 401, a second region 402, a deformation region 403, and/or a bezel region 404.

At least a portion of the first region 401 may be disposed on the first housing 310. For example, the first region 401 may be disposed only on the first housing 310. For example, the first region 401 may be disposed on the first housing 310 and a portion of the hinge structure 350. According to an embodiment, the first region 401 may include a plurality of pixels configured to emit light for providing visual information. The plurality of pixels within the first region 401 may emit the light for providing the visual information based on receiving a control signal from display driving circuitry (e.g., the DDI 230 of FIG. 2).

The second region 402 may be spaced apart from the first region 401. For example, the folding axis f may be disposed between the first region 402 and the second region 402. According to an embodiment, at least a portion of the second region 402 may be disposed on the second housing 320. For example, the second region 402 may be disposed only on the second housing 320. For example, the second region 402 may be disposed on the second housing 320 and another portion of the hinge structure 350. According to an embodiment, the second region 402 may be movable with respect to the first region 401. For example, as the second housing 320 moves with respect to the first housing 310, the second region 402 may move with respect to the first region 401. According to an embodiment, the second region 402 may include a plurality of pixels configured to emit light for providing visual information. The plurality of pixels within the second region 402 may emit the light for providing the visual information based on receiving a control signal from the display driving circuitry.

The deformation region 403 may be disposed between the first region 401 and the second region 402. For example, the deformation region 403 may connect the first region 401 and the second region 402. For example, the deformation region 403 may extend from the first region 401 to the second region 402. According to an embodiment, the deformation region 403 may be deformable by the movement of the second region 402 with respect to the first region 401. For example, the deformation region 403 may be folded by the movement of the second region 402 with respect to the first region 401. For example, the deformation region 403 may be unfolded by the movement of the second region 402 with respect to the first region 401. For example, the deformation region 403 may be bent with a curvature by the movement of the second region 402 with respect to the first region 401. According to an embodiment, the deformation region 403 may include a plurality of pixels configured to emit light to provide visual information. The plurality of pixels within the deformation region 403 may emit the light for providing the visual information, based on receiving a control signal from the display driving circuitry.

The bezel region 404 may refer, for example, to a region configured not to provide visual information among regions of the display 400. For example, the bezel region 404 may not include pixels for providing visual information. However, the disclosure is not limited thereto, and the bezel region 404 may include at least one pixel that does not emit light. For example, the bezel region 404 may refer, for example, to a region that is visually perceived as substantially black while the display 400 provides visual information. For example, the bezel region 404 may include circuits (e.g., the DDI 230 of FIG. 2) and/or a signal line for driving a plurality of pixels within the first region 401, the second region 402, and/or the deformation region 403. For example, the bezel region 404 may be referred to as a dead space of the display 400. According to an embodiment, the bezel region 404 may be connected to the first region 401, the second region 402, and/or the deformation region 403. For example, the bezel region 404 may surround the first region 401, the second region 402, and/or the deformation region 403. For example, the bezel region 404 may enclose the first region 401, the second region 402, and/or the deformation region 403. According to an embodiment, the bezel region 404 may define a periphery of the display 400. A periphery may be a region that includes a boundary that may distinguish a component from another component among regions included in the component, and the corresponding expression may be used substantially the same unless otherwise stated below.

According to an embodiment, the deformation region 403 may include a first periphery 403a, a second periphery 403b, a third periphery 403c, and/or a fourth periphery 403d. The first periphery 403a may be disposed between the first region 401 and the deformation region 403. The first periphery 403a may be connected to the first region 401. For example, the first periphery 403a may define a boundary between the first region 401 and the deformation region 403. According to an embodiment, the first periphery 403a may be substantially parallel to the folding axis f. The second periphery 403b may be disposed between the second region 402 and the deformation region 403. The second periphery 403b may be connected to the second region 402. For example, the second periphery 403b may define a boundary between the second region 402 and the deformation region 403. According to an embodiment, the second periphery 403b may be substantially parallel to the folding axis f. For example, the second periphery 403b may be substantially parallel to the first periphery 403a. The third periphery 403c may be disposed between the deformation region 403 and the bezel region 404. The third periphery 403c may connect the deformation region 403 and the bezel region 404. For example, the third periphery 403c may define a boundary between the deformation region 403 and the bezel region 404. According to an embodiment, the third periphery 403c may extend from the first periphery 403a to the second periphery 403b. For example, the third periphery 403c may extend from an end of the first periphery 403a to an end of the second periphery 403b. According to an embodiment, in the unfolding state of the electronic device 300, the third periphery 403c may be substantially perpendicular to a folding axis f. For example, in the unfolding state of the electronic device 300, the third periphery 403c may be substantially perpendicular to the first periphery 403a and/or the second periphery 403b. The fourth periphery 403d may be disposed between the deformation region 403 and the bezel region 404. The fourth periphery 403d may connect the deformation region 403 and the bezel region 404. For example, the fourth periphery 403d may define a boundary between the deformation region 403 and the bezel region 404. The fourth periphery 403d may be spaced apart from the third periphery 403c. According to an embodiment, the fourth periphery 403d may extend from the first periphery 403a to the second periphery 403b. For example, the fourth periphery 403d may extend from another end of the first periphery 403a to another end of the second periphery 403b. According to an embodiment, in the unfolding state of the electronic device 300, the fourth periphery 403d may be substantially perpendicular to the first periphery 403a and/or the second periphery 403b. For example, in the unfolding state of the electronic device 300, the fourth periphery 403d may be substantially parallel to the third periphery 403c.

According to an embodiment, the first periphery 403a may define a boundary between the first housing 310 and the hinge structure 350. In case that the first periphery 403a defines the boundary between the first housing 310 and the hinge structure 350, the first region 401 may be substantially the same as a first display region (e.g., the first display region 331 of FIG. 3A). According to an embodiment, in case that the first periphery 403a defines the boundary between the first housing 310 and the hinge structure 350, a shape of the first region 401 may not be changed when the display 400 is folded or unfolded. According to an embodiment, the second periphery 403b may define a boundary between the second housing 320 and the hinge structure 350. In case that the second periphery 403b defines the boundary between the second housing 320 and the hinge structure 350, the second region 402 may be substantially the same as a second display region (e.g., the second display region 332 of FIG. 3A). In case that the second periphery 403b defines the boundary between the second housing 320 and the hinge structure 350, a shape of the second region 402 may not be changed when the display 400 is folded or unfolded. However, the disclosure is not limited thereto. For example, each of the first periphery 403a and the second periphery 403b may not define the boundary between the first housing 310 and the hinge structure 350 and the boundary between the second housing 320 and the hinge structure 350. A description of other criteria that may distinguish a boundary of the deformation region 403 may be described with reference to FIG. 4B.

A graph of FIG. 4B indicates a relationship between stress applied in the display 400 and a distance spaced apart from the folding axis f while the display 400 is folded. In the graph of FIG. 4B, a horizontal axis indicates the distance spaced apart from the folding axis f, and a vertical axis indicates a size of the stress applied in the display 400.

Referring to FIG. 4B, according to an embodiment, the deformation region 403 may be a region in which a relatively more stress is applied among the regions of the display 400 in a state in which the display 400 is unfolded. The first periphery 403a of the deformation region 403, which is the boundary between the first region 401 and the deformation region 403, may be set based on an inflection point p1 of FIG. 4B. For example, the first periphery 403a may be defined at a point p2 spaced apart in a direction away from the folding axis f by a specified distance from the inflection point p1. For example, the first periphery 403a may be defined as the point p2 in which the first periphery 403a is spaced apart from the inflection point p1 along the direction away from the folding axis f by approximately 4 mm. In case that the first periphery 403a is defined as the point p2 of FIG. 4B, a portion of the first region 401 adjacent to the deformation region 403 may be deformable when the display 400 is folded or unfolded. However, the disclosure is not limited thereto, and a position of the first periphery 403a may correspond to the inflection point p1 of FIG. 4B.

According to an embodiment, the second periphery 403b of the deformation region 403, which is the boundary between the second region 402 and the deformation region 403, may be set based on the inflection point p1 of FIG. 4B. For example, the second periphery 403b may be defined at the point p2 spaced apart in the direction away from the folding axis f by the specified distance from the inflection point p1. For example, the second periphery 403b may be defined as the point p2 in which the second periphery 403b is spaced apart from the inflection point p1 along the direction away from the folding axis f by approximately 4 mm. In case that the second periphery 403b is defined as the point p2 of FIG. 4B, a portion of the second region 402 adjacent to the deformation region 403 may be deformable when the display 400 is folded or unfolded. However, the disclosure is not limited thereto, and a position of the second periphery 403b may correspond to the inflection point p1 of FIG. 4B.

For example, as the display 400 is folded or unfolded, stress may be generated inside the display 400. As folding or unfolding of the display 400 is repeated, stress may be generated in components in the display 400. Hereinafter, a structure that may reduce damage due to stress generated in the display 400 will be described in detail.

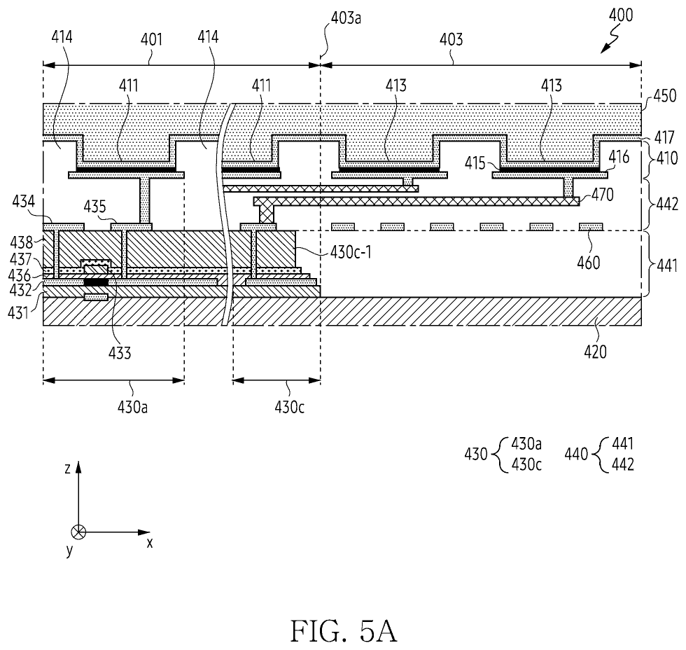

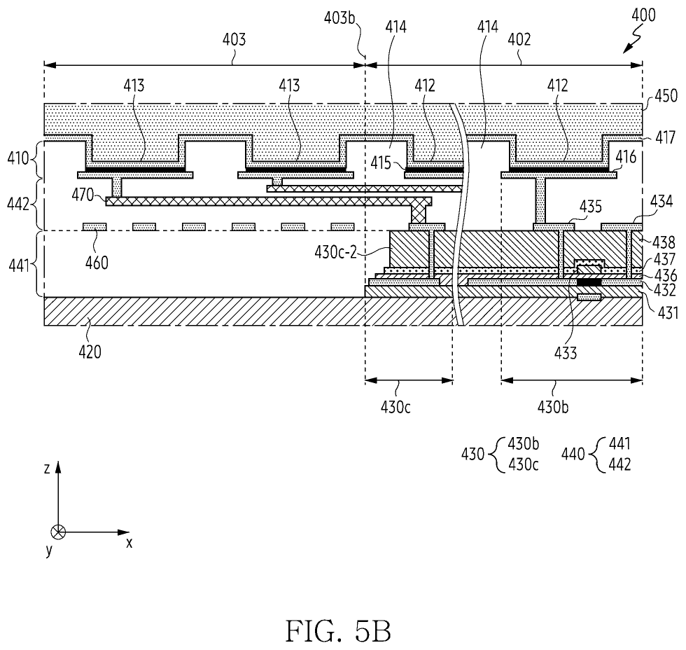

FIG. 5A is a cross-sectional view illustrating an example of a display of an example electronic device taken along line A-A′ of FIG. 4A according to various embodiments, and FIG. 5B is a cross-sectional view illustrating an example of a display of an example electronic device taken along line B-B′ of FIG. 4A according to various embodiments.

Referring to FIGS. 5A and 5B, according to an embodiment, a display 400 may include a pixel layer 410, a substrate 420, a plurality of thin film transistors 430 (TFTs), an organic insulation layer 440, an encapsulation layer 450, a plurality of dummy patterns 460, and/or a conductive line 470.

The pixel layer 410 may include a plurality of sub-pixels 411, 412, and 413 configured to emit light. Each of the plurality of sub-pixels 411, 412, and 413 may provide a specified color. For example, each of the plurality of sub-pixels 411, 412, and 413 may be configured to provide red light, green light, or blue light. A set of the plurality of sub-pixels 411, 412, and 413 may define a pixel. For example, the pixel may include one sub-pixel for emitting red light, two sub-pixels for emitting green light, and/or one sub-pixel for emitting blue light, but is not limited thereto. According to an embodiment, the pixel layer 410 may be disposed above the plurality of TFTs 430.

According to an embodiment, the pixel layer 410 may include a plurality of first sub-pixels 411, a plurality of second sub-pixels 412, a plurality of third sub-pixels 413, a pixel define member 414, an organic light emitting layer 415, a first electrode 416, and a second electrode 417. The plurality of first sub-pixels 411 may be disposed within a first region 401. For example, the plurality of first sub-pixels 411 may be included within the first region 401. The plurality of second sub-pixels 412 may be disposed within a second region 402. For example, the plurality of second sub-pixels 412 may be included within the second region 402. The plurality of third sub-pixels 413 may be disposed within a deformation region 403. For example, the plurality of third sub-pixels 413 may be included within the deformation region 403. The plurality of sub-pixels 411, 412, and 413 may be distinguished by the pixel define member 414. For example, the pixel define member 414 may distinguish each of the plurality of sub-pixels 411, 412, and 413 by surrounding each of the plurality of sub-pixels 411, 412, and 413. By being distinguished by the pixel define member 414, interference of light emitted from the plurality of sub-pixels 411, 412, and 413 may be reduced. According to an embodiment, the pixel define member 414 may include an organic material. For example, a ratio of the organic material included in the pixel define member 414 may be higher than a ratio of an inorganic material included in the pixel define member 414. For example, the pixel define member 414 may be referred to as a pixel define layer (PDL). The organic light emitting layer 415 may be configured to emit light based on energy generated by an electron and a hole. According to an embodiment, the organic light emitting layer 415 may be included in each of the plurality of sub-pixels 411, 412, and 413. The first electrode 416 may be disposed below the organic light emitting layer 415. The first electrode 416 may be electrically connected to the plurality of TFTs 430. According to an embodiment, the first electrode 416 may be included in each of the plurality of sub-pixels 411, 412, and 413. For example, the first electrode 416 may be an anode. In case that the first electrode 416 is the anode, the first electrode 416 may transmit a hole to the organic light emitting layer 415 by an electric field applied from the plurality of TFTs 430. The second electrode 417 may be disposed above the organic light emitting layer 415. The second electrode 417 may be disposed along the pixel define member 414. For example, the second electrode 417 may surround the pixel define member 414. According to an embodiment, the second electrode 417 may be included in each of the plurality of sub-pixels 411, 412, and 413. For example, the second electrode 417 may be a cathode. In case that the second electrode 417 is the cathode, the second electrode 417 may transmit an electron to the organic light emitting layer 415 by the electric field applied from the plurality of TFTs 430. As the hole and the electron transmitted from the first electrode 416 and the second electrode 417 are transmitted to the organic light emitting layer 415, the organic light emitting layer 415 may emit light. For example, light may be emitted from the organic light emitting layer 415 toward above (e.g., a +z direction) the pixel layer 410, but is not limited thereto. For example, light may be emitted from the organic light emitting layer 415 toward below (e.g., a −z direction) the pixel layer 410.

The substrate 420 may support various components included in the display 400. For example, the substrate 420 may support the plurality of TFTs 430. The substrate 420 may be disposed below the pixel layer 410. According to an embodiment, the substrate 420 may be disposed within the first region 401, the second region 402, and/or the deformation region 403. The substrate 420 may be included within the first region 401, the second region 402, and/or the deformation region 403. For example, the substrate 420 may be disposed within the first region 401 and the second region 402 across the deformation region 403. According to an embodiment, the substrate 420 may have flexibility so that the display 400 may be folded or unfolded. For example, the substrate 420 may include polyimide (PI), but is not limited thereto.

The plurality of TFTs 430 may drive the plurality of sub-pixels 411, 412, and 413 in the pixel layer 410. For example, the plurality of TFTs 430 may be manufactured based on low temperature polycrystalline silicon (LTPS) or low temperature polycrystalline oxide (LTPO). According to an embodiment, the plurality of TFTs 430 may be disposed below the pixel layer 410. For example, the plurality of TFTs 430 may be disposed between the substrate 420 and the pixel layer 410. For example, the plurality of TFTs 430 may be disposed on the substrate 420. According to an embodiment, the plurality of TFTs 430 may include an inorganic material. For example, a ratio of the inorganic material included in the plurality of TFTs 430 may be greater than a ratio of an organic material included in the plurality of TFTs 430. According to an embodiment, the number of the plurality of TFTs 430 may correspond to the number of the plurality of sub-pixels 411, 412, and 413. For example, the number of the plurality of TFTs 430 may be substantially the same as the number of the plurality of sub-pixels 411, 412, and 413. However, the disclosure is not limited thereto, and the number of the plurality of TFTs 430 may be smaller than the number of the plurality of sub-pixels 411, 412, and 413.

According to an embodiment, the plurality of TFTs 430 may include a buffer layer 431, an active layer 432, a gate electrode 433, a source electrode 434, a drain electrode 435, a first insulation layer 436, a second insulation layer 437, and/or a middle insulation layer 438. According to an embodiment, each of the plurality of TFTs 430 may include the gate electrode 433, the source electrode 434, and the drain electrode 435. The plurality of TFTs 430 may share the buffer layer 431, the active layer 432, the first insulation layer 436, the second insulation layer 437, and/or the middle insulation layer 438. For example, one TFT of the plurality of TFTs 430 may be defined as a concept including the gate electrode 433, the source electrode 434, and the drain electrode 435. For example, the number of the plurality of TFTs 430 may correspond to the number of the gate electrodes 433. For example, the number of the plurality of TFTs 430 may correspond to the number of the source electrodes 434. For example, the number of the plurality of TFTs 430 may correspond to the number of the drain electrodes 435.

The buffer layer 431 may reduce an amount of a foreign matter penetrating into the plurality of TFTs 430 when the display 400 is manufactured. For example, the buffer layer 431 may block an inflow of a foreign matter into the active layer 432. According to an embodiment, the buffer layer 431 may be disposed on the substrate 420. For example, the buffer layer 431 may contact the substrate 420.

The active layer 432 may provide a passage through which an electron moving from the source electrode 434 to the drain electrode 435 can move. According to an embodiment, the active layer 432 may be disposed on the substrate 420. For example, the active layer 432 may be disposed on the buffer layer 431. For example, the active layer 432 may contact the buffer layer 431. According to an embodiment, the active layer 432 may include low-temperature polycrystalline silicon (LTPS).

The gate electrode 433 may apply an electric field for the movement of the electron from the source electrode 434 to the drain electrode 435. According to an embodiment, the gate electrode 433 may be disposed on the active layer 432.

The source electrode 434 and the drain electrode 435 may be connected to the active layer 432. For example, the source electrode 434 and the drain electrode 435 may be electrically connected to the active layer 432 through a contact hole. According to an embodiment, the source electrode 434 and the drain electrode 435 may be disposed above the active layer 432 and the gate electrode 433. The source electrode 434 and the drain electrode 435 may be electrically connected to the gate electrode 433. In case that the gate electrode 433 applies an electric field to the active layer 432, a current may flow from the source electrode 434 to the drain electrode 435. A n electric field generated by the flow of the current from the source electrode 434 to the drain electrode 435 may be applied to the first electrode 416 and/or the second electrode 417 in the pixel layer 410. As the electric field is applied to the first electrode 416 and/or the second electrode 417, light may be emitted from the organic light emitting layer 415.

The first insulation layer 436 may suppress a short between the active layer 432 and the gate electrode 433. The first insulation layer 436 may be interposed between the active layer 432 and the gate electrode 433. For example, the first insulation layer 436 may be disposed on the active layer 432. According to an embodiment, the first insulation layer 436 may include an inorganic material. For example, the first insulation layer 436 may be formed of the inorganic material. For example, the first insulation layer 436 may be referred to as a gate insulator (GI).

The second insulation layer 437 may be disposed on the first insulation layer 436. For example, the second insulation layer 437 may surround the gate electrode 433. According to an embodiment, the second insulation layer 437 may include an inorganic material. For example, the second insulation layer 437 may be formed of the inorganic material. For example, the second insulation layer 437 may be referred to as a gate insulator (GI).

The middle insulation layer 438 may suppress a short circuit between the gate electrode 433 and the source electrode 434. The middle insulation layer 438 may suppress a short circuit between the gate electrode 433 and the drain electrode 435. According to an embodiment, the middle insulation layer 438 may be disposed between the gate electrode 433 and the source electrode 434. The middle insulation layer 438 may be disposed between the gate electrode 433 and the drain electrode 435. The middle insulation layer 438 may be disposed on the second insulation layer 437. According to an embodiment, the middle insulation layer 438 may include an inorganic material. For example, the intermediate insulation layer 438 may be formed of the inorganic material. For example, the intermediate insulation layer 438 may be referred to as an interlayer dielectric layer (ILD).

The organic insulation layer 440 may cover the plurality of TFTs 430. According to an embodiment, the organic insulation layer 440 may be disposed between the plurality of TFTs 430 and the pixel layer 410. The organic insulation layer 440 may be disposed on the plurality of TFTs 430. As the organic insulation layer 440 is disposed on the plurality of TFTs 430, a space in which the pixel layer 410 is disposed may be secured, when the display 400 is manufactured. For example, the organic insulation layer 440 may be referred to as a passivation layer. According to an embodiment, the organic insulation layer 440 may include an organic material. For example, a ratio of the organic material included in the organic insulation layer 440 may be higher than a ratio of an inorganic material included in the organic insulation layer 440.

The encapsulation layer 450 may encapsulate the plurality of sub-pixels 411, 412, and 413 in the pixel layer 410. The encapsulation layer 450 may block an inflow of a foreign matter (e.g., moisture) and/or oxygen into the plurality of sub-pixels 411, 412, and 413. According to an embodiment, the encapsulation layer 450 may be disposed on the pixel layer 410. For example, the encapsulation layer 450 may cover the plurality of sub-pixels 411, 412, and 413. For example, the encapsulation layer 450 may be disposed on the plurality of sub-pixels 411, 412, and 413. The encapsulation layer 450 may be disposed on the second electrode 417. According to an embodiment, the encapsulation layer 450 may include an organic layer and an inorganic layer laminated to each other. For example, the encapsulation layer 450 may be referred to as a thin film encapsulation layer (TFE).

According to an embodiment, the plurality of TFTs 430 may include a plurality of first TFTs 430a, a plurality of second TFTs 430b, and/or a plurality of third TFTs 430c. The plurality of first TFTs 430a may be disposed within the first region 401.

The plurality of first TFTs 430a may be configured to drive the plurality of first sub-pixels 411 disposed within the first region 401. For example, each of the plurality of first TFTs 430a may be electrically connected to each of the plurality of first sub-pixels 411. According to an embodiment, the plurality of first TFTs 430a may be disposed outside the deformation region 403. For example, the plurality of first TFTs 430a may be disposed within the first region 401. For example, the plurality of first TFTs 430a may be spaced apart from the deformation region 403.

The plurality of second TFTs 430b may be disposed within the second region 402. The plurality of second TFTs 430b may be configured to drive the plurality of second sub-pixels 412 disposed within the second region 402. For example, each of the plurality of second TFTs 430b may be electrically connected to each of the plurality of second sub-pixels 412. According to an embodiment, the plurality of second TFTs 430b may be disposed outside the deformation region 403. For example, the plurality of second TFTs 430b may be disposed within the second region 402. For example, the plurality of second TFTs 430b may be spaced apart from the deformation region 403.

The plurality of third TFTs 430c may be configured to drive the plurality of third sub-pixels 413 within the deformation region 403. For example, the plurality of third TFTs 430c may be electrically connected to the plurality of third sub-pixels 413. According to an embodiment, the plurality of third TFTs 430c may be disposed outside the deformation region 403. The plurality of third TFTs 430c may be disposed within a different region from the deformation region 403, among the first region 401, the second region 402, and the deformation region 403. The plurality of third TFTs 430c may be disposed within at least one of the first region 401 and the second region 402. For example, the plurality of TFTs 430 may not be disposed within the deformation region 403 of the display 400. For example, the plurality of third TFTs 430c may be disposed within the first region 401. In case that the plurality of third TFTs 430c are disposed within the first region 401, the deformation region 403 may be close to the plurality of third TFTs 430c among the plurality of first TFTs 430a and the plurality of third TFTs 430c, but is not limited thereto. For example, the plurality of third TFTs 430c may be disposed within the second region 402. In case that the plurality of third TFTs 430c are disposed within the second region 402, the deformation region 403 may be close to the plurality of third TFTs 430c among the plurality of second TFTs 430b and the plurality of third TFTs 430c, but is not limited thereto. For example, as the plurality of TFTs 430 include the inorganic material, the plurality of TFTs 430 may have brittleness. As the plurality of TFTs 430 has the brittleness, when folding or unfolding of the display 400 is repeated, the plurality of TFTs 430 may be damaged. Since the plurality of third TFTs 430c for driving the plurality of third sub-pixels 413 within the deformation region 403 are disposed outside the deformation region 403, the display 400 according to an embodiment may provide a structure that may reduce damage due to stress generated by deformation of the display 400.

According to an embodiment, a ratio of an inorganic material included within the deformation region 403 may be different from a ratio of an inorganic material included within the first region 401. For example, the ratio of the inorganic material included within the deformation region 403 may be lower than the ratio of the inorganic material included within the first region 401. For example, the ratio of the inorganic material included within the deformation region 403 may be higher than the ratio of the inorganic material included within the first region 401. The ratio of the inorganic material included within the deformation region 403 may be different from a ratio of an inorganic material included within the second region 402. For example, the ratio of the inorganic material included within the deformation region 403 may be lower than the ratio of the inorganic material included within the second region 402. For example, the ratio of the inorganic material included within the deformation region 403 may be higher than the ratio of the inorganic material included within the second region 402.

According to an embodiment, a portion 430c-1 of the plurality of third TFTs 430c may be spaced apart from another portion 430c-2 of the plurality of third TFTs 430c. The portion 430c-1 of the plurality of third TFTs 430c may be disposed within the first region 401. For example, the portion 430c-1 of the plurality of third TFTs 430c may be disposed along a first periphery 403a of the deformation region 403 within the first region 401. The other portion 430c-2 of the plurality of third TFTs 430c may be disposed within the second region 402. For example, the other portion 430c-2 of the plurality of third TFTs 430c may be disposed along a second periphery 403b of the deformation region 403 within the second region 402. According to an embodiment, the portion 430c-1 of the plurality of third TFTs 430c and the other portion 430c-2 of the plurality of third TFTs 430c may be disposed on the substrate 420. For example, the portion 430c-1 of the plurality of third TFTs 430c and the other portion 430c-2 of the plurality of third TFTs 430c may be supported by the substrate 420.

According to an embodiment, the organic insulation layer 440 may include a first portion 441 and/or a second portion 442. The first portion 441 may be disposed within the deformation region 403. The first portion 441 may be disposed on the substrate 420. The first portion 441 may be disposed between the portion 430c-1 of the plurality of third TFTs 430c and the other portion 430c-2 of the plurality of third TFTs 430c. The first portion 441 may fill a gap between the portion 430c-1 of the plurality of third TFTs 430c and the other portion 430c-2 of the plurality of third TFTs 430c. The first portion 441 may contact the substrate 420 between the portion 430c-1 of the plurality of third TFTs 430c and the other portion 430c-2 of the plurality of third TFTs 430c. The second portion 442 may be disposed within the first region 401, the second region 402, and the deformation region 403. For example, the second portion 442 may extend from the first region 401 to the second region 402 across the deformation region 403. According to an embodiment, the second portion 442 may be disposed on the plurality of TFTs 430. For example, the second portion 442 may be disposed on the portion 430c-1 of the plurality of third TFTs 430c, the other portion 430c-2 of the plurality of third TFTs 430c, and the first portion 441. For example, since brittleness of an organic material is lower than brittleness of an inorganic material, brittleness of the organic insulation layer 440 may be lower than the brittleness of the plurality of TFTs 430. The display 400 according to an embodiment may provide a structure that is robust to stress by the organic insulation layer 440 filling the gap between the portion 430c-1 of the plurality of third TFTs 430c and the other portion 430c-2 of the plurality of third TFTs 430c spaced apart from each other within the deformation region 403.

According to an embodiment, the plurality of third TFTs 430c may include a step structure. For example, the portion 430c-1 of the plurality of third TFTs 430c adjacent to the first periphery 403a of the deformation region 403 may include the step structure. For example, the other portion 430c-2 of the plurality of third TFTs 430c adjacent to the second periphery 403b of the deformation region 403 may include the step structure. The buffer layer 431 in the plurality of third TFTs 430c may define a step with respect to at least one of the active layer 432, the first insulation layer 436, the second insulation layer 437, and the middle insulation layer 438. For example, the buffer layer 431 in the plurality of third TFTs 430c may define the step with respect to the middle insulation layer 438. According to an embodiment, a distance from the first periphery 403a to the buffer layer 431 of the deformation region 403 may be different from a distance from the first periphery 403a of the deformation region 403 to the middle insulation layer 438. For example, a distance spaced apart from the first periphery 403a may increase in an order of the buffer layer 431, the active layer 432, the first insulation layer 436, the second insulation layer 437, and the middle insulation layer 438. However, the disclosure is not limited thereto. For example, the distance spaced apart from the first periphery 403a may be reduced in the order of the buffer layer 431, the active layer 432, the first insulation layer 436, the second insulation layer 437, and the middle insulation layer 438.

The plurality of dummy patterns 460 may compensate for reflectance of the deformation region 403. For example, the plurality of dummy patterns 460 may reduce a difference between the reflectance of the deformation region 403 and reflectance of the first region 401. For example, the plurality of dummy patterns 460 may reduce a difference between the reflectance of the deformation region 403 and reflectance of the second region 402. According to an embodiment, the plurality of dummy patterns 460 may be disposed within the deformation region 403. For example, the plurality of dummy patterns 460 may be disposed between the portion 430c-1 of the plurality of third TFTs 430c and the other portion 430c-2 of the plurality of third TFTs 430c. According to an embodiment, the plurality of dummy patterns 460 may be disposed inside a portion of the organic insulation layer 440 within the deformation region 403. For example, the plurality of dummy patterns 460 may be disposed between the first portion 441 and the second portion 442. For example, the plurality of dummy patterns 460 may be disposed on the first portion 441, but is not limited thereto. For example, the plurality of dummy patterns 460 may be disposed inside the first portion 441 or inside the second portion 442. According to an embodiment, the plurality of dummy patterns 460 may include conductive members spaced apart from each other. However, the disclosure is not limited thereto, and the plurality of dummy patterns 460 may include only one conductive member extending within the deformation region 403.

The conductive line 470 may connect the plurality of third sub-pixels 413 and the plurality of third TFTs 430c. For example, the conductive line 470 may electrically connect the plurality of third sub-pixels 413 and the plurality of third TFTs 430c. According to an embodiment, the conductive line 470 may electrically connect at least one of the plurality of third sub-pixels 413 to the portion 430c-1 of the plurality of third TFTs 430c. The conductive line 470 may electrically connect at least one of the plurality of third sub-pixels 413 to the other portion 430c-2 of the plurality of third TFTs 430c. According to an embodiment, the conductive line 470 may extend from the outside of the deformation region 403 to the inside of the deformation region 403. For example, the conductive line 470 may extend from the drain electrode 435 (or the source electrode 434) of the portion 430c-1 of the plurality of third TFTs 430c disposed within the first region 401 to the plurality of third sub-pixels 413 disposed within the deformation region 403. The conductive line 470 may connect the drain electrode 435 (or the source electrode 434) of the portion 430c-1 of the plurality of third TFTs 430c to the first electrode 416 of the plurality of third sub-pixels 413. For example, the conductive line 470 may extend from the drain electrode 435 (or the source electrode 434) of the other portion 430c-2 of the plurality of third TFTs 430c disposed within the second region 402 to the plurality of third sub-pixels 413 disposed within the deformation region 403. The conductive line 470 may connect the drain electrode 435 (or the source electrode 434) of the other portion 430c-2 of the plurality of third TFTs 430c and the first electrode 416 of the plurality of third sub-pixels 413. As the plurality of third TFTs 430c and the plurality of third sub-pixels 413 are electrically connected by the conductive line 470, light may be emitted from the plurality of third sub-pixels 413 in the deformation region 403. According to an embodiment, the conductive line 470 may include the plurality of conductive lines 470. For example, the number of the conductive lines 470 may correspond to the number of the plurality of third TFTs 430c.

As described above, since the plurality of third TFTs 430c including the inorganic material are disposed outside the deformation region 403, the display 400 according to an embodiment may provide the structure that may reduce damage to the display 400 due to stress.

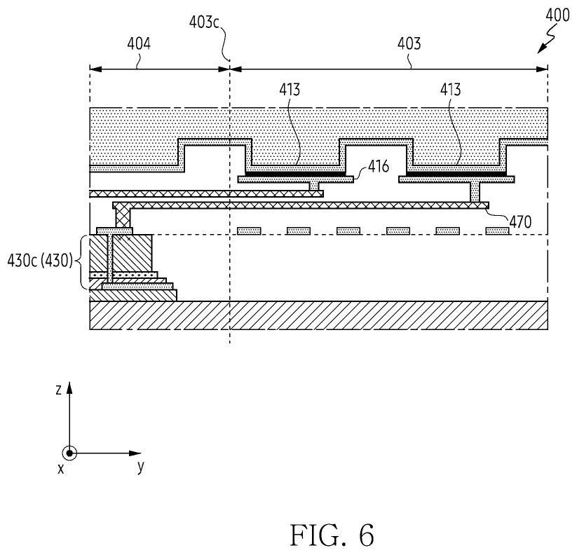

FIG. 6 is a cross-sectional view illustrating an example of a display of an example electronic device taken along line C-C′ of FIG. 4A according to various embodiments.

Referring to FIG. 6, according to an embodiment, a plurality of third TFTs 430c may be disposed within a bezel region 404. For example, the plurality of third TFTs 430c may be disposed along a third periphery 403c between the bezel region 404 and a deformation region 403. However, the disclosure is not limited thereto. For example, the plurality of third TFTs 430c may be disposed along a fourth periphery (e.g., the fourth periphery 403d of FIG. 4A) between the bezel region 404 and the deformation region 403.

According to an embodiment, a conductive line 470 may connect the plurality of third TFTs 430c disposed within the bezel region 404 and a plurality of third sub-pixels 413 disposed within the deformation region 403. The conductive line 470 may electrically connect the plurality of third TFTs 430c disposed within the bezel region 404 and the plurality of third sub-pixels 413 disposed within the deformation region 403. For example, the conductive line 470 may extend from a drain electrode 435 (or the source electrode 434 of FIGS. 5A and 5B) of the plurality of third TFTs 430c disposed within the bezel region 404 to a first electrode 416 of the plurality of third sub-pixels 413 disposed within the deformation region 403.

As described above, since the plurality of third TFTs 430c having brittleness are disposed outside the deformation region 403, a display 400 according to an embodiment may provide a structure that may reduce damage to the display 400 due to stress.

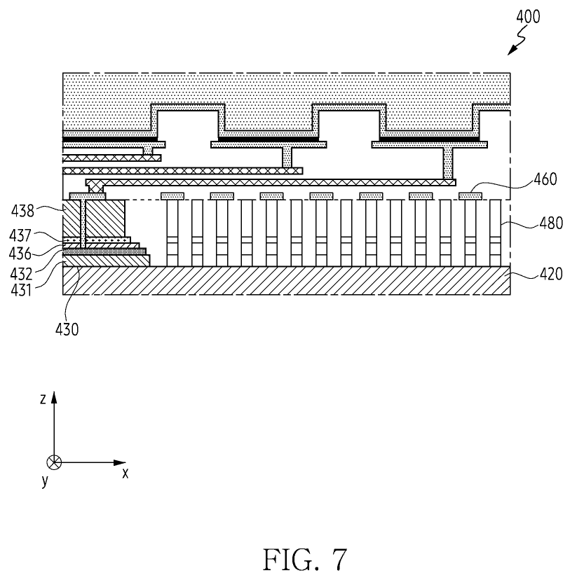

FIG. 7 is a cross-sectional view illustrating an example of cutting a display of an example electronic device according to various embodiments.

Referring to FIG. 7, a display 400 according to an embodiment may include an inorganic member 480. The inorganic member 480 may reduce propagation of a crack within a deformation region 403. The inorganic member 480 may include an inorganic material. For example, the inorganic member 480 may include substantially the same material as a plurality of TFTs 430. For example, the inorganic member 480 may have brittleness, but is not limited thereto. For example, the inorganic member 480 may include metal having flexibility.

According to an embodiment, a thickness of the inorganic member 480 may correspond to a thickness of each of the plurality of third TFTs 430c. A thickness of one component may refer, for example, to a length extending in an above direction (e.g., a +z direction), and a corresponding expression may be applied substantially the same unless otherwise stated below. For example, the inorganic member 480 may include substantially the same material as a layers except for a gate electrode (e.g., the gate electrode 433 of FIGS. 5A and 5B), a source electrode (e.g., the source electrode 434 of FIGS. 5A and 5B), and a drain electrode (e.g., the drain electrode 435 of FIGS. 5A and 5B), among components included in the plurality of TFTs 430. For example, the inorganic member 480 may include substantially the same material as a buffer layer 431, an active layer 432, a first insulation layer 436, and/or a middle insulation layer 438.

According to an embodiment, the inorganic member 480 may be disposed within the deformation region 403. For example, the inorganic member 480 may be disposed in a portion of an organic insulation layer 440 within the deformation region 403. For example, the inorganic member 480 may be disposed in a first portion 441 of the organic insulation layer 440. However, the disclosure is not limited thereto, and the inorganic member 480 may be disposed in a second portion 442. According to an embodiment, the inorganic member 480 may be disposed on a substrate 420. For example, the inorganic member 480 may extend along the direction (e.g., the +z direction) facing upward from the substrate 420. For example, the inorganic member 480 may contact one of a plurality of dummy patterns 460 by extending from the substrate 420. According to an embodiment, the inorganic member 480 may include a plurality of inorganic members spaced apart from each other. However, the disclosure is not limited thereto, and the inorganic member 480 may be integrally formed within the deformation region 403.

As described above, the display 400 according to an embodiment may provide a structure that may reduce damage to the deformation region 403 by the inorganic member 480 disposed within the deformation region 403.

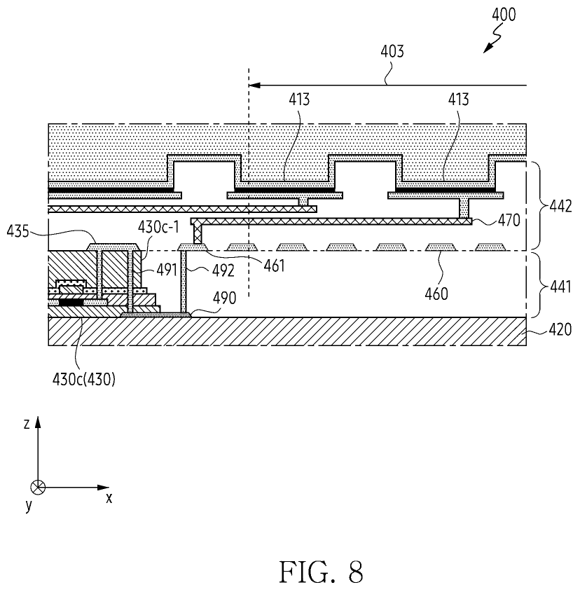

FIG. 8 is a cross-sectional view illustrating an example of cutting a display of an example electronic device according to various embodiments.

Referring to FIG. 8, according to an embodiment, a display 400 may include a bottom metal layer 490 (BM L). The bottom metal layer 490 may reduce an amount of light from the outside of the display 400 transmitted to a plurality of TFTs 430. For example, the bottom metal layer 490 may reflect the light incident on the plurality of TFTs 430 by being disposed below the plurality of TFTs 430. According to an embodiment, the bottom metal layer 490 may be disposed between the plurality of TFTs 430 and a substrate 420. For example, the bottom metal layer 490 may be disposed between a buffer layer 431 and the substrate 420. For example, the bottom metal layer 490 may be disposed between a portion 430c-1 of a plurality of third TFTs 430c and the substrate 420. However, the disclosure is not limited thereto, and the bottom metal layer 490 may be disposed between another portion (e.g., the other portion 430c-2 of FIGS. 4A and 4B) of the plurality of third TFTs 430c and the substrate 420.

Hereinafter, it will be described based on a relationship between the portion 430c-1 of the plurality of third TFTs 430c and the bottom metal layer 490, but this is for convenience of explanation. The explanation of the relationship between the portion 430c-1 of the plurality of third TFTs 430c and the bottom metal layer 490 may be applied substantially the same to a relationship between the other portion 430c-2 of the plurality of third TFTs 430c and the bottom metal layer 490.

According to an embodiment, the bottom metal layer 490 may be electrically connected to the portion 430c-1 of the plurality of third TFTs 430c. The bottom metal layer 490 may be electrically connected to the portion 430c-1 of the plurality of third TFTs 430c through a first conductive member 491. The first conductive member 491 may connect the bottom metal layer 490 to a drain electrode 435 (or the source electrode 434 of FIGS. 5A and 5B) of the portion 430c-1 of the plurality of third TFTs 430c. For example, the first conductive member 491 may penetrate the portion 430c-1 of the plurality of third TFTs 430c.

According to an embodiment, the bottom metal layer 490 may be electrically connected to one 461 of a plurality of dummy patterns 460. For example, the bottom metal layer 490 may be electrically connected to the one 461 of the plurality of dummy patterns 460 through a second conductive member 492. The second conductive member 492 may extend from the bottom metal layer 490 to the one 461 of the plurality of dummy patterns 460. For example, the second conductive member 492 may penetrate a first portion 441 within a deformation region 403.

According to an embodiment, a conductive line 470 may extend from the inside of the deformation region 403. The conductive line 470 may electrically connect a plurality of third sub-pixels 413 disposed inside the deformation region 403 and the plurality of third TFTs 430 disposed outside the deformation region 403 by extending from inside the deformable region 403. For example, the conductive line 470 may connect the one 461 of the plurality of dummy patterns 460 and at least one of the plurality of third sub-pixels 413. As the one 461 of the plurality of dummy patterns 460 and the at least one of the plurality of third sub-pixels 413 are connected by the conductive line 470, the portion 430c-1 of the plurality of third TFTs 430c and at least one of the plurality of third sub-pixels 413 may be electrically connected.

As described above, the display 400 according to an embodiment may provide a structure that may connect the plurality of third sub-pixels 413 disposed within the deformation region 403 and the portion 430c-1 of the plurality of third TFTs 430c disposed outside the deformation region 403 by the conductive line 470 connected within the deformation region 403.

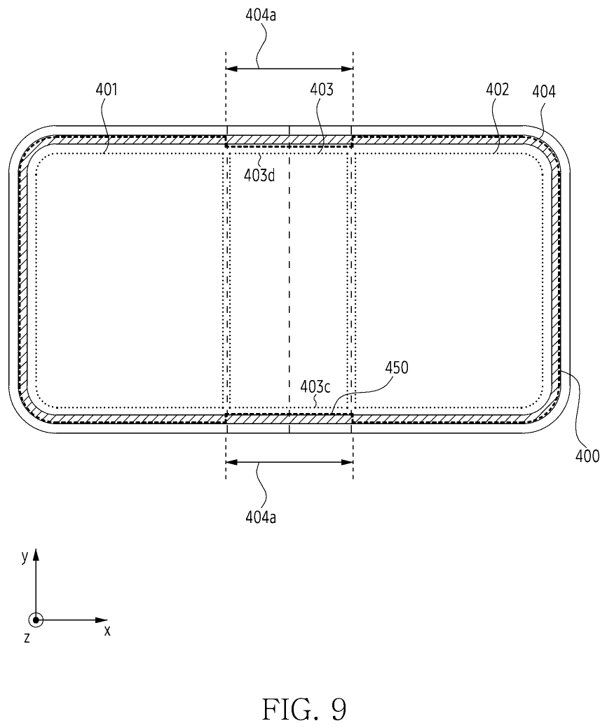

FIG. 9 is a diagram illustrating a top plan view in an unfolding state of an example electronic device according to various embodiments.

Referring to FIG. 9, according to an embodiment, an encapsulation layer 450 may be disposed within a first region 401, a second region 402, and a deformation region 403. The encapsulation layer 450 may be disposed outside a portion 404a of a bezel region 404. The portion 404a of the bezel region 404 may surround the deformation region 403. For example, the portion 404a of the bezel region 404 may refer, for example, to a portion of the bezel region 404 surrounding a third periphery 403c of the deformation region 403. For example, the portion 404a of the bezel region 404 may refer, for example, to a portion of the bezel region 404 surrounding a fourth periphery 403d of the deformation region 403. For example, as the encapsulation layer 450 includes one or more inorganic layers, the encapsulation layer 450 may have brittleness. As the encapsulation layer 450 has the brittleness, stress generated by folding or unfolding of a display 400 may damage the encapsulation layer 450. In case that the encapsulation layer 450 is omitted, damage to pixels in the display 400 may occur due to moisture or oxygen. The display 400 according to an embodiment may provide a structure that may reduce damage to the display 400 by the encapsulation layer 450 disposed outside the portion 404a of the bezel region 404 in which a pixel is not disposed. For example, as the encapsulation layer 450 corresponding to the portion 404a of the bezel region 404 in which the pixel is not disposed is deleted, the display 400 may provide a structure that may reduce damage to the encapsulation layer 450 due to stress.

As described above, the display 400 according to an embodiment may provide a structure that may reduce damage to the display 400 by the encapsulation layer 450 including a notch in the portion 404a of the bezel region 404. For example, since the encapsulation layer 450 includes the notch in the portion 404a of the bezel region 404, an area of the encapsulation layer 450 including an inorganic material may be reduced. As the area of the encapsulation layer 450 including the inorganic material is reduced, damage due to stress of the display 400 may be reduced.

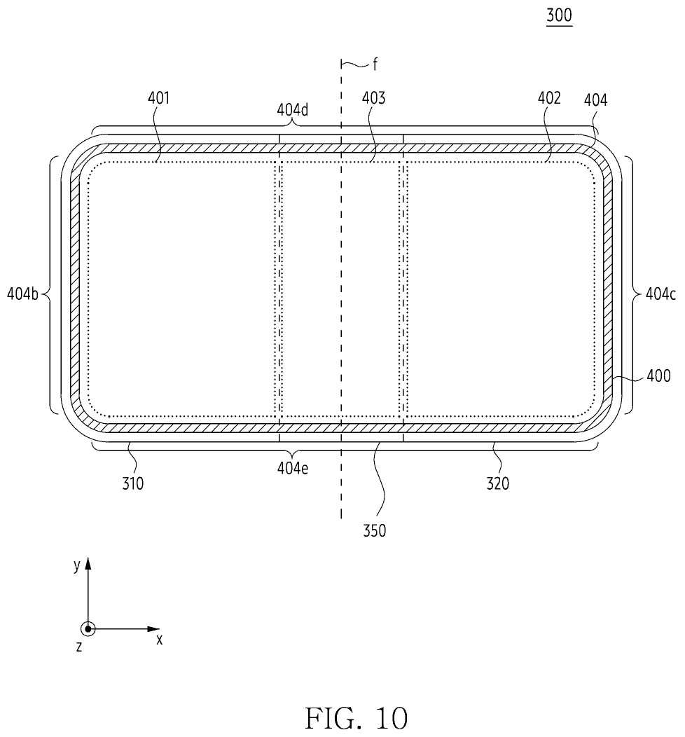

FIG. 10 is a diagram illustrating a top plan view in an unfolding state of an example electronic device according to various embodiments.

Referring to FIG. 10, according to an embodiment, a bezel region 404 may include a first bezel portion 404b, a second bezel portion 404c, a third bezel portion 404d, and/or a fourth bezel portion 404e. The first bezel portion 404b may be disposed on a first housing 310. The first bezel portion 404b may be substantially parallel to a folding axis f. For example, the first bezel portion 404b may be disposed along a periphery of a first region 401 that is substantially parallel to the folding axis f. The second bezel portion 404c may be disposed on a second housing 320. The second bezel portion 404c may be substantially parallel to the folding axis f. For example, the second bezel portion 404c may be disposed along a periphery of a second region 402 that is substantially parallel to the folding axis f. According to an embodiment, the second bezel portion 404c may be spaced apart from the first bezel portion 404b. For example, the folding axis f may be positioned between the first bezel portion 404b and the second bezel portion 404c. For example, the second bezel portion 404c may be opposite to the first bezel portion 404b. For example, the second bezel portion 404c may face the first bezel portion 404b. The third bezel portion 404d may connect the first bezel portion 404b and the second bezel portion 404c. The third bezel portion 404d may be disposed between the first bezel portion 404b and the second bezel portion 404c. For example, the third bezel portion 404d may extend from an end of the first bezel portion 404b to an end of the second bezel portion 404c. For example, the third bezel portion 404d may extend from the first housing 310 to the second housing 320 across a hinge structure 350. According to an embodiment, in the unfolding state of the electronic device 300, the third bezel portion 404d may be substantially perpendicular to the folding axis f. The fourth bezel portion 404e may connect the first bezel portion 404b and the second bezel portion 404c. The fourth bezel portion 404e may be disposed between the first bezel portion 404b and the second bezel portion 404c. For example, the fourth bezel portion 404e may extend from another end of the first bezel portion 404b to another end of the second bezel portion 404c. For example, the fourth bezel portion 404e may extend from the first housing 310 to the second housing 320 across the hinge structure 350. According to an embodiment, in the unfolding state of the electronic device 300, the fourth bezel portion 404e may be substantially perpendicular to the folding axis f. The fourth bezel portion 404e may be spaced apart from the third bezel portion 404d. For example, the fourth bezel portion 404e may be opposite to the third bezel portion 404d. For example, the fourth bezel portion 404e may face the third bezel portion 404d.

According to an embodiment, a plurality of third TFTs (e.g., the plurality of third TFTs 430c of FIGS. 5A and 5B) may be disposed within the bezel region 404 of the display 400. In case that a DDI (e.g., the DDI 230 of FIG. 2) is disposed in one of the first bezel portion 404b and the second bezel portion 404c, the plurality of third TFTs 430c may be disposed in at least one of a portion of the third bezel portion 404d disposed on the hinge structure 350 and a portion of the fourth bezel portion 404e disposed on the hinge structure. For example, in case that the DDI 230 is disposed in the first bezel portion 404b, a plurality of third TFTs 430c may be disposed in the portion of the third bezel portion 404d disposed on the hinge structure 350 and the portion of the fourth bezel portion 404e disposed on the hinge structure. For example, in case that the DDI 230 is disposed in the second bezel portion 404c, the plurality of third TFTs 430c may be disposed in the portion of the third bezel portion 404d disposed on the hinge structure 350 and the portion of the fourth bezel portion 404e disposed on the hinge structure.

According to an embodiment, in case that the DDI 230 is disposed in one of the third bezel portion 404d and the fourth bezel portion 404e, the plurality of third TFTs 430c may be disposed in another bezel portion opposite to a bezel portion in which the DDI 230 is disposed. In case that the DDI 230 is disposed on one of the third bezel portion 404d and the fourth bezel portion 404e, the plurality of third TFTs 430c may be disposed in the other bezel portion facing the bezel portion in which the DDI 230 is disposed. For example, in case that the DDI 230 is disposed in the third bezel portion 404d, the plurality of third TFTs 430c may be disposed in a portion of the fourth bezel portion 404e overlapping the hinge structure 350. For example, in case that the DDI 230 is disposed in the fourth bezel portion 404e, the plurality of third TFTs 430c may be disposed in a portion of the third bezel portion 404d overlapping the hinge structure 350.

As described above, since the plurality of third TFTs 430c are disposed outside a deformation region 403, the display 400 according to an embodiment may provide a structure that may reduce damage to the display 400.

In order to provide a variety of content to a user, a display may be bent with a curvature. For example, the display may be referred to as a flexible display that may be folded or unfolded. Stress generated by repetition of folding or folding of the display may damage at least a portion of components inside the display. For example, stress generated in the display may damage components having brittleness inside the display. The display and an electronic device including the same may need a structure that may reduce damage due to stress generated by a change in a shape of the display.

The technical problems addressed in the present disclosure are not limited to those described above, and other technical problems not mentioned herein will be clearly understood by those having ordinary knowledge in the art to which the present disclosure belongs, from the following description.

According to an example embodiment, a display (e.g., the display 400 of FIG. 4A) may comprise: a first region (e.g., the first region 401 of FIG. 4A; a second region (e.g., the second region 402 of FIG. 4A) movable with respect to the first region; a deformation region (e.g., the deformation region 403 of FIG. 4A), disposed between the first region and the second region, deformable by movement of the second region with respect to the first region; a pixel layer (e.g., the pixel layer 410 of FIGS. 5A and 5B) including a plurality of first sub-pixels (e.g., the plurality of first sub-pixels 411 of FIG. 5A) disposed within the first region, a plurality of second sub-pixels (e.g., the plurality of second sub-pixels 412 of FIG. 5B) disposed within the second region, and a plurality of third sub-pixels (e.g., the plurality of third sub-pixels 413 of FIGS. 5A and 5B) disposed within the deformation region; and a plurality of thin film transistors (TFTs) (e.g., the plurality of TFTs 430 of FIGS. 5A and 5B) disposed below the pixel layer, wherein the plurality of TFTs may include a plurality of first TFTs (e.g., the plurality of first TFTs 430a of FIG. 5A) configured to drive the plurality of first sub-pixels, disposed inside the first region, a plurality of second TFTs (e.g., the plurality of second TFTs 430b of FIG. 5B) configured to drive the plurality of second sub-pixels, disposed inside the second region, and a plurality of third TFTs (e.g., the plurality of third TFTs 430c of FIGS. 5A and 5B) configured to drive at least a portion of the plurality of third sub-pixels, the third TFTs being disposed outside the deformation region.

Since the plurality of third TFTs having relatively brittleness are disposed outside the deformation region of the display, the display according to an embodiment may provide a structure that is robust against damage due to stress.

According to an example embodiment, the plurality of third TFTs may be disposed within at least one of the first region and the second region.

Since the plurality of third TFTs having relatively brittleness are disposed within at least one of the first region and the second region outside the deformation region of the display, the display according to an embodiment may provide the structure that is robust against damage due to the stress.

According to an example embodiment, the display may comprise: a bezel region (e.g., the bezel region 404 of FIG. 4A) surrounding the first region, the second region, and the deformation region, wherein a portion of the plurality of third TFTs may be disposed within the bezel region.

Since the plurality of third TFTs having relatively brittleness are disposed within the bezel region outside the deformation region of the display, the display according to an embodiment may provide the structure that is robust against damage due to the stress.

According to an example embodiment, the display may comprise a plurality of dummy patterns (e.g., the plurality of dummy patterns 460 of FIGS. 5A and 5B) disposed within the deformation region.

The display according to an embodiment may provide a structure that may reduce a difference in reflectance between the deformation region and another region in the display by the plurality of dummy patterns disposed within the deformation region.

According to an example embodiment, a ratio of inorganic material within the deformation region may be lower than a ratio of inorganic material included within the first region.

Since the ratio of the inorganic material within the deformation region is reduced as the plurality of third TFTs are disposed outside the deformation region, the display according to an embodiment may provide the structure that is robust against damage.

According to an example embodiment, the display may comprise a conductive line (e.g., the conductive line 470 of FIG. 5A) electrically connecting a portion (e.g., the portion 430c-1 of FIG. 5A) of the plurality of third TFTs and at least one of the plurality of third sub-pixels.

The display according to an embodiment may provide visual information through the deformation region by the conductive line connected to the plurality of third sub-pixels disposed within the deformation region.

According to an example embodiment, the conductive line may extend from the outside of the deformation region to the at least one of the plurality of third sub-pixels within the deformation region.

The display according to an embodiment may provide the visual information through the deformation region by the conductive line extending from the outside of the deformation region.

According to an example embodiment, the display may comprise a substrate (e.g., the substrate 420 of FIGS. 5A and 5B), disposed within the first region, the second region, and the deformation region, supporting a portion (e.g., the portion 430c-1 of FIG. 5A) of the plurality of third TFTs and another portion (e.g., the other portion 430c-2 of FIG. 5B) of the plurality of third TFTs spaced apart from the portion of the plurality of third TFTs. According to an example embodiment, the display may comprise an organic insulation layer (e.g., the organic insulation layer 440 of FIGS. 5A and 5B) including a first portion (e.g., the first portion 441 of FIGS. 5A and 5B) disposed on the substrate to fill a gap between the portion of the plurality of third TFTs and the another portion of the plurality of third TFTs and a second portion (e.g., the second portion 442 of FIGS. 5A and 5B) disposed on the first portion, the portion of the plurality of third TFTs, and the another portion of the plurality of third TFTs.

The display according to an embodiment may provide the structure that is robust against damage by the organic insulation layer filling a space between the plurality of third TFTs.

According to an example embodiment, the display may comprise a bottom metal layer (e.g., the bottom metal layer 490 of FIG. 8), disposed between the substrate and the portion of the plurality of third TFTs, electrically connected to one of the plurality of third TFTs. According to an example embodiment, the display may comprise a plurality of dummy patterns (e.g., the plurality of dummy patterns 460 of FIG. 8), disposed on the first portion, spaced apart from each other. According to an example embodiment, the display may comprise a conductive member (e.g., the second conductive member 492 of FIG. 8) connecting the bottom metal layer and one (e.g., the one 461 of the plurality of dummy patterns 460 of FIG. 8) of the plurality of dummy patterns. According to an example embodiment, the display may comprise a conductive line (e.g., the conductive line 470 of FIG. 8) electrically connecting the portion of the plurality of third TFTs and at least one of the plurality of third sub-pixels by connecting the one of the plurality of dummy patterns and the at least one of the plurality of third sub-pixels.

The display according to an embodiment may be configured to provide the visual information through the deformation region by the conductive line electrically connecting the plurality of third TFTs and the plurality of third sub-pixels.

According to an example embodiment, the plurality of third TFTs may include a buffer layer (e.g., the buffer layer 431 of FIGS. 5A and 5B) disposed on the substrate. According to an example embodiment, the plurality of third TFTs may include an active layer (e.g., the active layer 432 of FIGS. 5A and 5B) disposed on the buffer layer. According to an example embodiment, the plurality of third TFTs may include a middle insulating layer (e.g., the middle insulating layer 438 of FIGS. 5A and 5B) disposed on the active layer.

According to an example embodiment, the buffer layer may define a step with respect to the middle insulating layer.

Since the buffer layer and the middle layer define the step, the display according to an embodiment may provide a structure that may reduce damage due to stress generated by folding or unfolding the display.

According to an example embodiment, the display may comprise an inorganic member (e.g., the inorganic member 480 of FIG. 7), disposed within the deformation region, spaced apart from each other.

The display according to an embodiment may provide a structure that may reduce propagation of a crack within the deformation region by the inorganic member disposed within the deformation region.

According to an example embodiment, a thickness of the inorganic member may correspond to a thickness of each of the plurality of third TFTs.

The display according to an embodiment may provide the structure that may reduce the propagation of the crack in the deformation region by the inorganic member corresponding to the thickness of the plurality of third TFTs.

According to an example embodiment, the display may comprise an encapsulation layer (e.g., the encapsulation layer 450 of FIGS. 5A and 5B), disposed within the first region, the second region, and the deformation region, covering the pixel layer.

The display according to an embodiment may provide a structure that may reduce contact between the plurality of sub-pixels and a foreign matter by the encapsulation layer covering the plurality of sub-pixels.

According to an example embodiment, the display may comprise a bezel region (e.g., the bezel region 404 of FIG. 4A) surrounding the first region, the second region, and the deformation region. According to an example embodiment, when viewing the display from above, the encapsulation layer may be disposed outside at least a portion (e.g., the portion 404a of FIG. 9) of the bezel region.

The display according to an embodiment may provide a structure in which an area of the encapsulation layer including the inorganic material is reduced by the encapsulation layer disposed outside the bezel region.

According to an example embodiment, an electronic device may comprise a first housing (e.g., the first housing 310 of FIG. 4A). According to an example embodiment, the electronic device may comprise a second housing (e.g., the second housing 320 of FIG. 4A) coupled to the first housing so as to be rotatable with respect to the first housing. According to an example embodiment, the electronic device may comprise a display (e.g., the display 400 of FIG. 4A) including a first region (e.g., the first region 401 of FIG. 4A), a second region (e.g., the second region 402 of FIG. 4A) spaced apart from the first region, and a deformation region (e.g., the deformation region 403 of FIG. 4A) connecting the first region and the second region and being deformable by movement of the second housing with respect to the first housing. According to an example embodiment, the display may comprise a pixel layer (e.g., the pixel layer 410 of FIGS. 5A and 5B) including a plurality of first sub-pixels (e.g., the plurality of first sub-pixels 411 of FIG. 5A) disposed within the first region, a plurality of second sub-pixels (e.g., the plurality of second sub-pixels 412 of FIG. 5B) disposed within the second region, and a plurality of third sub-pixels (e.g., the plurality of third sub-pixels 413 of FIGS. 5A and 5B) disposed within the deformation region. According to an example embodiment, the display may comprise a plurality of thin film transistors (TFTs) (e.g., the plurality of TFTs 430 of FIGS. 5A and 5B) disposed below the pixel layer. According to an example embodiment, the plurality of TFTs may include a plurality of first TFTs (e.g., the plurality of first TFTs 430a of FIG. 5A) configured to drive the plurality of first sub-pixels, disposed inside the first region. According to an example embodiment, the plurality of TFTs may include a plurality of second TFTs (e.g., the plurality of second TFTs 430b of FIG. 5B) configured to drive the plurality of second sub-pixels, disposed inside the second region. According to an example embodiment, the plurality of TFTs may include a plurality of third TFTs (e.g., the plurality of third TFTs 430c of FIGS. 5A and 5B) configured to drive at least a portion of the plurality of third sub-pixels, the third TFTs being disposed outside the deformation region.

Since the plurality of third TFTs having relatively brittleness are disposed outside the deformation region of the display, the electronic device according to an embodiment may provide a structure that is robust against damage due to stress.

According to an example embodiment, the plurality of third TFTs may be disposed within at least one of the first region and the second region.

Since the plurality of third TFTs having relatively brittleness are disposed within at least one of the first region and the second region outside the deformation region of the display, the electronic device according to an embodiment may provide the structure that is robust against damage due to the stress.

According to an example embodiment, the display may comprise a bezel region (e.g., the bezel region 404 of FIG. 4A) surrounding the first region, the second region, and the deformation region. According to an embodiment, a portion of the plurality of third TFTs may be disposed within the bezel region.

Since the plurality of third TFTs having relatively brittleness are disposed within the bezel region outside the deformation region of the display, the electronic device according to an embodiment may provide the structure that is robust against damage due to the stress.

According to an example embodiment, the display may comprise a plurality of dummy patterns (e.g., the plurality of dummy patterns 460 of FIGS. 5A and 5B) disposed within the deformation region.

The electronic device according to an embodiment may provide a structure that may reduce a difference in reflectance between the deformation region and another region in the display by the plurality of dummy patterns disposed within the deformation region.

According to an example embodiment, the display may comprise a conductive line (e.g., the conductive line 470 of FIG. 5A) electrically connecting a portion (e.g., the portion 430c-1 of FIG. 5A) of the plurality of third TFTs and at least one of the plurality of third sub-pixels.

The electronic device according to an embodiment may provide visual information through the deformation region by the conductive line connected to the plurality of third sub-pixels disposed within the deformation region.

The effects that may be obtained from the present disclosure are not limited to those described above, and any other effects not mentioned herein will be clearly understood by those skilled in the art to which the present disclosure belongs, from the following description.

Meanwhile, relative terms such as “lower” or “bottom” and “upper” or “top” may be used herein to describe a relationship of one component to another as illustrated in the drawings. It should be understood that the relative terms encompass other orientations of a device in addition to an orientation depicted in the drawings. For example, elements described as being “lower” of other elements may be oriented “upper” of the other elements in case that the device is flipped over in one of the drawings. Therefore, the term “lower” may include both “lower” and “upper” orientations, according to a specific orientation of the drawing. Similarly, in case that the device in one of the drawings is flipped, elements described as being “below” or “beneath” other elements may be oriented “above” the other elements. Therefore, the terms “below” or “beneath” may include both an above or below orientation.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (A SIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various modifications, changes and alternatives of the various embodiments with be apparent without departing from the true spirit and full scope of the disclosure, including the appended claims and their equivalents. It will also be understood that any of the embodiment(s) described herein may be used in conjunction with any other embodiment(s) described herein.

What is claimed is:

1. A display comprising:
a first region;
a second region movable with respect to the first region;
a deformation region, disposed between the first region and the second region, deformable by movement of the second region with respect to the first region;
a pixel layer including a plurality of first sub-pixels disposed within the first region, a plurality of second sub-pixels disposed within the second region, and a plurality of third sub-pixels disposed within the deformation region; and
a plurality of thin film transistors (TFTs) disposed below the pixel layer, and
wherein the plurality of TFTs include:
a plurality of first TFTs configured to drive the plurality of first sub-pixels, disposed inside the first region;
a plurality of second TFTs configured to drive the plurality of second sub-pixels, disposed inside the second region; and
a plurality of third TFTs configured to drive at least a portion of the plurality of third sub-pixels, the plurality of third TFTs being disposed outside the deformation region.

2. The display of claim 1,
wherein the plurality of third TFTs are disposed inside at least one of the first region and the second region.

3. The display of claim 1, further comprising a bezel region surrounding the first region, the second region, and the deformation region, and
wherein a portion of the plurality of third TFTs is disposed within the bezel region.

4. The display of claim 1, comprising a plurality of dummy patterns disposed within the deformation region.

5. The display of claim 1,
wherein a ratio of inorganic material within the deformation region is lower than a ratio of inorganic material included within the first region.

6. The display of claim 1, further comprising a conductive line electrically connecting a portion of the plurality of third TFTs and at least one of the plurality of third sub-pixels.

7. The display of claim 6,
wherein the conductive line extends from the outside the deformation region to at least one of the plurality of third sub-pixels within the deformation region.

8. The display of claim 1, further comprising:
a substrate, disposed within the first region, the second region, and the deformation region, supporting a portion of the plurality of third TFTs and another portion of the plurality of third TFTs spaced apart from the portion of the plurality of third TFTs;
an organic insulation layer including a first portion disposed on the substrate to fill a gap between the portion of the plurality of third TFTs and the another portion of the plurality of third TFTs and a second portion disposed on the first portion, the portion of the plurality of third TFTs, and the another portion of the plurality of third TFTs.

9. The display of claim 8, further comprising:
a bottom metal layer, disposed between the substrate and the portion of the plurality of third TFTs, and electrically connected to at least one of the plurality of third TFTs;
a plurality of dummy patterns, disposed on the first portion, spaced apart from each other;
a conductive member comprising a conductive material connecting the bottom metal layer and one of the plurality of dummy patterns; and
a conductive line electrically connecting the portion of the plurality of third TFTs and at least one of the plurality of third sub-pixels by connecting the one of the plurality of dummy patterns and the at least one of the plurality of third sub-pixels.

10. The display of claim 1,
wherein the plurality of third TFTs include:
a buffer layer disposed on the substrate;
an active layer disposed on the buffer layer; and
a middle insulating layer disposed on the active layer.

11. The display of claim 10,
wherein the buffer layer defines a step with respect to the middle insulating layer.

12. The display of claim 1, further comprising an inorganic member comprising an inorganic material, disposed within the deformation region, spaced apart from each other.

13. The display of claim 12,
wherein a thickness of the inorganic member corresponds to a thickness of each of the plurality of third TFTs.

14. The display of claim 1, further comprising an encapsulation layer, disposed within the first region, the second region, and the deformation region, and covering the pixel layer.

15. The display of claim 14, further comprising a bezel region surrounding the first region, the second region, and the deformation region,
wherein, when viewing the display from above, the encapsulation layer is disposed outside at least a portion of the bezel region.

16. An electronic device, comprising:
a first housing;
a second housing coupled to the first housing to be rotatable with respect to the first housing; and
a display including a first region, a second region spaced apart from the first region, and a deformation region connecting the first region and the second region and being deformable by movement of the second housing with respect to the first housing,
wherein the display further includes:
a pixel layer including a plurality of first sub-pixels disposed within the first region, a plurality of second sub-pixels disposed within the second region, and a plurality of third sub-pixels disposed within the deformation region; and
a plurality of thin film transistors (TFTs) disposed below the pixel layer, wherein the plurality of TFTs include:
a plurality of first TFTs configured to drive the plurality of first sub-pixels, disposed inside the first region;
a plurality of second TFTs configured to drive the plurality of second sub-pixels, disposed inside the second region; and
a plurality of third TFTs configured to drive at least a portion of the plurality of third sub-pixels, the plurality of third TFTs being disposed outside the deformation region.

17. The electronic device of claim 16,
wherein the plurality of third TFTs are disposed inside at least one of the first region and the second region.

18. The electronic device of claim 16, further comprising a bezel region surrounding the first region, the second region, and the deformation region, and
wherein a portion of the plurality of third TFTs is disposed within the bezel region.

19. The electronic device of claim 16, comprising a plurality of dummy patterns disposed within the deformation region.

20. The electronic device of claim 16, further comprising a conductive line electrically connecting a portion of the plurality of third TFTs and at least one of the plurality of third sub-pixels.
